(19) United States
(12) Patent Application Publication
(10) Pub. No.: US 2023/0255081 A1
(43) Pub. Date: Aug. 10, 2023

(54) DISPLAY DEVICE

(71) Applicant: Samsung Display Co., Ltd., Yongin-si (KR)

(72) Inventors: SEONGYEON LEE, Asan-si (KR); JEONGKI KIM, Hwaseong-si (KR); JONG-HOON KIM, Seoul (KR); KYOUNGHAE MIN, Asan-si (KR); HYEJUN WOO, Asan-si (KR); MYOUNGJONG LEE, Cheonan-si (KR); SUJIN LEE, Hwaseong-si (KR); SI-WAN JEON, Hwaseong-si (KR); HAKBUM CHOI, Cheonan-si (KR)

(73) Assignee: Samsung Display Co., Ltd., Yongin-si (KR)

(21) Appl. No.: 18/076,519

(22) Filed: Dec. 7, 2022

(30) Foreign Application Priority Data
Feb. 9, 2022 (KR) 10-2022-0017054

(51) Int. Cl. H01L 51/00

(52) U.S. Cl. CPC H01L 27/322

(57) ABSTRACT

A display device includes a display substrate including a display area, a non-display area adjacent to the display area, and light emitting elements disposed in the display area. The display device includes a light control substrate facing the display substrate and including a color filter layer, a light conversion layer, and a low refractive index layer disposed between the color filter layer and the light conversion layer. The color filter layer extends from the display area to the non-display area and includes a first surface facing the display substrate, and the first surface includes a step difference overlapping the non-display area.

### CROSS-REFERENCE TO RELATED APPLICATION(S)

This U.S. non-provisional patent application claims priority to and benefits of Korean Patent Application No. 10-2022-0017054 under 35 U.S.C. § 119, filed on Feb. 9, 2022 in the Korean Intellectual Property Office, the entire contents of which are hereby incorporated by reference.

### BACKGROUND

### 1. Technical Field

The disclosure relates to a display device with improved reliability.

### 2. Description of the Related Art

Multimedia display devices, such as televisions, mobile phones, tablet computers, computers, navigation units, and game units, include a display substrate to display images. The display substrate may include pixels displaying the images, and each of the pixels may include a light emitting element emitting a light and a driving element electrically connected to the light emitting element.

The display device may include various functional layers to improve a light emitting efficiency and a color purity thereof. However, pollutant substances, such as gas or moisture can flow into the display device through the functional layers that may be relatively vulnerable to permeability, and as a result, defects may occur in the display device.

### SUMMARY

The disclosure provides a display device with improved reliability by blocking an inflow path of gas or moisture flowing into a low refractive index layer adjacent to an edge of the display device and preventing deterioration and defects of the display device.

Embodiments provide a display device that may include a display substrate including a display area, and a non-display area adjacent to the display area, and light emitting elements disposed in the display area, and a light control substrate facing the display substrate and including a color filter layer, a light conversion layer, and a low refractive index layer disposed between the color filter layer and the light conversion layer. The color filter layer may extend from the display area to the non-display area and may include a first surface facing the display substrate. The first surface may include a step difference overlapping the non-display area.

The color filter layer may include a first color filter, a second color filter, and a third color filter that each include a rear surface extending from the display area to the non-display area and facing the low refractive index layer. The first color filter, the second color filter, and the third color filter may overlap each other in the non-display area.

An edge of the first color filter may be disposed on the rear surface of the second color filter to form the step difference.

An edge of the first color filter may be disposed on the rear surface of the third color filter to form the step difference.

The step difference may include a first step difference portion and a second step difference portion. An edge of the first color filter may be disposed on the rear surface of the second color filter to form the first step different portion. An edge of the second color filter may be disposed on the rear surface of the third color filter to form the second step different portion.

The low refractive index layer may cover the step difference.

The low refractive index layer may include a first portion, and a second portion spaced apart from the first portion in the non-display area.

The low refractive index layer may have a thickness that decreases as a distance from the step difference decreases.

The first color filter, the second color filter, and the third color filter may have different colors relative to each other.

The light conversion layer may include a bank portion including openings defined therethrough to correspond to the light emitting elements, and a light conversion portion and a light transmission portion that may be respectively disposed in the openings. The light conversion portion may include a quantum dot converting a wavelength of a source light of the light emitting element.

The first color filter, the second color filter, and the third color filter may overlap each other in an area in which the bank portion may be disposed.

The low refractive index layer may have a refractive index less than a refractive index of the light conversion portion.

The light conversion portion may include a first light conversion portion converting the source light to a first color light, and a second light conversion portion converting the source light to a second color light. The first color filter may overlap the first light conversion portion, the second color filter may overlap the second light conversion portion, and the third color filter may overlap the light transmission portion.

The light control substrate may further include a capping layer that may be in contact with the low refractive index layer and cover an edge of the low refractive layer.

The display device may further include a sealing member disposed between the display substrate and the light control substrate to overlap the non-display area, and the step difference may be disposed closer to an outer side of the light control substrate than the sealing member may be in a plan view.

Embodiments provide a display device that may include a display substrate including a display area, a non-display area adjacent to the display area, and light emitting elements disposed in the display area. The display device may include an upper substrate including a rear surface facing the display substrate, a color filter layer disposed on the rear surface of the upper substrate, a light conversion layer disposed between the display substrate and the color filter layer, and a low refractive index layer disposed between the color filter layer and the light conversion layer. The color filter layer may include a first color filter, a second color filter, and a third color filter that extend from the display area to the non-display area and may be sequentially disposed in a direction from the low refractive index layer to the upper substrate, an edge of the third color filter may protrude more than an edge of the first color filter toward an outer side of the upper substrate, and the edge of the first color filter may be covered by the low refractive index layer.

An edge of the second color filter may be aligned with the edge of the first color filter.

An edge of the second color filter may be aligned with the edge of the third color filter.

An edge of the second color filter may be covered by the first color filter.

An edge of the second color filter may protrude more than the edge of the first color filter toward the outer side of the upper substrate, and the edge of the third color filter may protrude more than the edge of the second color filter toward the outer side of the upper substrate.

According to the above, the low refractive index layer may be disposed on a surface of the color filter layer having the step difference, and the low refractive index layer may have a thin thickness on the step difference of the color filter layer or a continuity of the low refractive index layer may be blocked. Thus, an inflow path of gas or moisture flowing into the low refractive index layer disposed adjacent to an edge of the display device may be blocked, and the display device may be prevented from being deteriorated.

As the display device may include the low refractive index layer that blocks the inflow of the gas or moisture, a light emitting efficiency of the display device may be improved, a separation of substrates of the display device may be prevented, and an occurrence of a spot in an area adjacent to the edge of the display device may be prevented. Accordingly, a reliability of the display device may be improved.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic perspective view of a display device according to an embodiment of the disclosure;

FIG. 2 is an exploded schematic perspective view of a display device according to an embodiment of the disclosure;

FIG. 3 is a schematic cross-sectional view of a display module according to an embodiment of the disclosure;

FIG. 4 is a schematic plan view of a display substrate according to an embodiment of the disclosure;

FIG. 5 is an enlarged schematic plan view of a display substrate according to an embodiment of the disclosure;

FIG. 6 is a schematic cross-sectional view of a display substrate according to an embodiment of the disclosure;

FIG. 7 is a schematic cross-sectional view of a display module according to an embodiment of the disclosure;

FIG. 8 is a schematic cross-sectional view of a display module according to an embodiment of the disclosure;

FIGS. 9A and 9B are enlarged schematic cross-sectional views of display modules in area AA of FIG. 8 according to embodiments of the disclosure; and

FIGS. 10A to 10C are enlarged schematic cross-sectional views of display modules in area AA of FIG. 8 according to embodiments of the disclosure.

### DETAILED DESCRIPTION OF THE EMBODIMENTS

The disclosure may be variously modified and realized in many different forms, and thus specific embodiments will be provided only as examples in the drawings and described in detail hereinbelow. However, the disclosure should not be limited to the specific disclosed forms, but rather should be construed to include all modifications, equivalents, or replacements included in the spirit and scope of the disclosure.

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components may be exaggerated for effective description of the technical content. As used herein, the term “and/or” may include any and all combinations of one or more of the associated listed items. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “comprise,” “comprising,” “include,” “including,” “has,” and “having,” when used in this disclosure, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

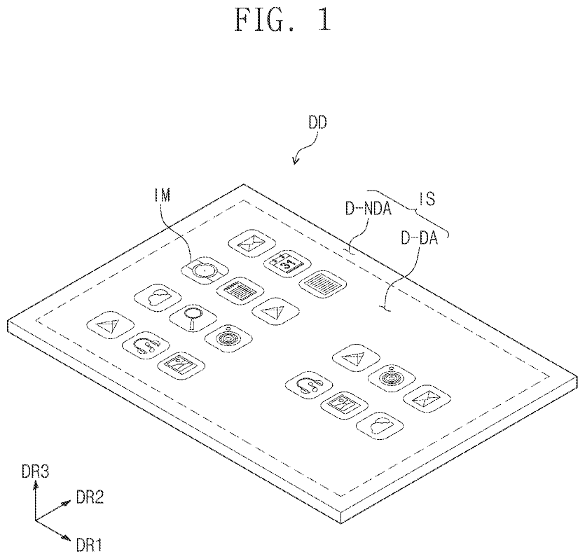

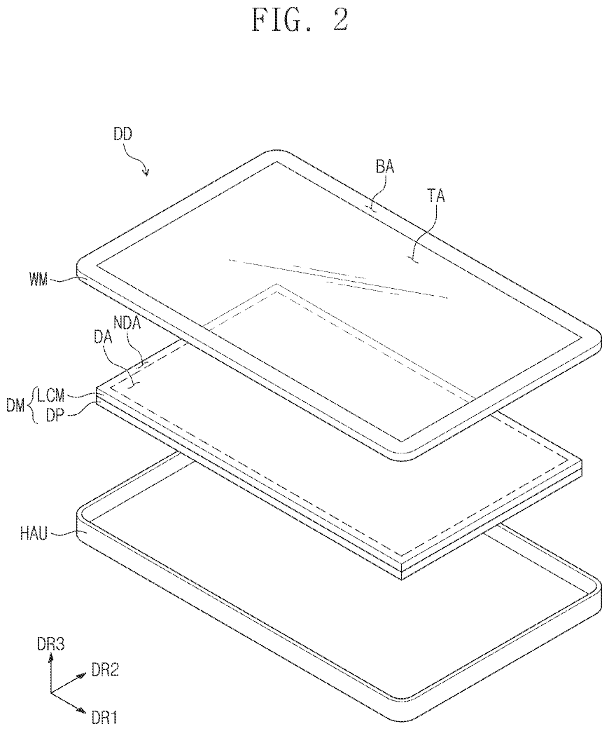

FIG. 1 is a schematic perspective view of a display device DD according to an embodiment of the disclosure. FIG. 2 is an exploded schematic perspective view of the display device DD according to an embodiment of the disclosure.

The display device DD may be activated in response to electrical signals and may display an image IM. The display device DD may include various embodiments to provide the image IM to a user. As an example, the display device DD may be applied to a large-sized electronic device, such as a television set, an outdoor billboard, etc., and a small and medium-sized electronic device, such as a monitor, a mobile phone, a tablet computer, a computer, a navigation unit, a game unit, etc. However, these are merely examples, and the display device DD may be applied to other electronic devices as long as they do not depart from the spirit of the disclosure.

Referring to FIG. 1, the display device DD may have a rectangular shape with long sides extending in a first direction DR1 and short sides extending in a second direction DR2 crossing the first direction DR1. However, the shape of the display device DD should not be limited to the rectangular shape, and the display device DD may have a variety of shapes, such as a circular shape, a polygonal shape, etc.

The display device DD may display the image IM through a display surface IS toward a third direction DR3, which may be substantially perpendicular to a plane defined by the first direction DR1 and the second direction DR2. A normal line direction of the display surface IS may be substantially parallel to the third direction DR3. The display surface IS through which the image IM may be displayed may correspond to a front surface of the display device DD. The image IM may include a still image as well as a video. FIG. 1 shows application icons as a representative example of the image IM.

In an embodiment, front (or upper) and rear (or lower) surfaces of each member (or each unit) of the display device DD may be defined with respect to a direction in which the image IM may be displayed. The front and rear surfaces may be opposite to each other in the third direction DR3, and a normal line direction of each of the front and rear surfaces may be substantially parallel to the third direction DR3. A separation distance between the front and rear surfaces of each member (or each unit) in the third direction DR3 may correspond to a thickness of the member (or the unit).

In the disclosure, the expression “in a plan view” may mean a state of being viewed in the third direction DR3. In the disclosure, the expression “when viewed in a cross-section” may mean a state of being viewed in the first direction DR1 or the second direction DR2. Directions indicated by the first, second, and third directions DR1, DR2, and DR3 may be relative to each other, and thus, the directions indicated by the first, second, and third directions DR1, DR2, and DR3 may be changed to other directions.

The display surface IS of the display device DD may include a display part D-DA and a non-display part D-NDA. The display part D-DA may be a part where the image IM may be displayed within the front surface of the display device DD, and a user may view the image IM through the display part D-DA. In an embodiment, the display part D-DA having a quadrangular shape in a plane is illustrated as a representative example, however, the display part D-DA may have a variety of shapes depending on a design of the display device DD.

The non-display part D-NDA may be a part where the image IM may not displayed within the front surface of the display device DD. The non-display part D-NDA may have a color and may block a light. The non-display part D-NDA may be disposed adjacent to the display part D-DA. As an example, the non-display part D-NDA may be disposed outside of the display part D-DA and may surround the display part D-DA, however, this is merely an example. The non-display part D-NDA may be defined adjacent to only a side of the display part D-DA or may be defined in a side surface rather than the front surface of the display device DD. According to an embodiment, the non-display part D-NDA may be omitted.

FIG. 1 shows the display device DD including a flat display surface IS as a representative example. However, the shape of the display surface IS of the display device DD should not be limited thereto or thereby, and the display surface IS may have a curved or three-dimensional shape.

The display device DD may be flexible. The term “flexible” used herein refers to the property of being able to be bent from a structure that may be completely bent to a structure that may be bent at the scale of a few nanometers. For example, the display device DD may be a curved display device or a foldable display device. According to an embodiment, the display device DD may be rigid.

According to an embodiment, the display device DD may sense an external input applied thereto from the outside. The external input may include a variety of external inputs provided from the outside, such as pressure, temperature, light, etc. The external input may include a proximity input (e.g., a hovering input) applied in case approaching close to or adjacent to the display device DD at a distance as well as a touch input, (e.g., a touch by a hand of a user or a pen).

Referring to FIG. 2, the display device DD may include a window WM, a display module DM, and an external case HAU. The display module DM may include a display substrate DP and a light control substrate LCM disposed on the display substrate DP.

The window WM may be coupled with the external case HAU to form an external appearance of the display device DD and to provide an inner space in which components, e.g., the display module DM, of the display device DD may be accommodated.

The window WM may be disposed on the display module DM. The window WM may protect the display module DM from external impacts. A front surface of the window WM may correspond to the display surface IS (refer to FIG. 1) of the display device DD. The front surface of the window WM may include a transmission area TA and a bezel area BA.

The transmission area TA of the window WM may be an optically transparent area. The window WM may transmit the image IM provided from the display module DM through the transmission area TA, and the user may view the image IM. The transmission area TA of the window WM may correspond to the display part D-DA (refer to FIG. 1) of the display device DD.

The window WM may include an optically transparent insulating material. As an example, the window WM may include a glass, sapphire, and/or plastic material. The window WM may have a single-layer or multi-layer structure. The window WM may further include functional layers, such as an anti-fingerprint layer, a phase control layer, a hard coating layer, etc., disposed on an optically transparent substrate.

The bezel area BA of the window WM may be obtained by depositing, coating, or printing a material having a color on the optically transparent substrate. The bezel area BA of the window WM may prevent components of the display module DM, which may be disposed to overlap the bezel area BA, from being viewed from the outside. The bezel area BA may correspond to the non-display part D-NDA (refer to FIG. 1) of the display device DD.

The display module DM may be disposed between the window WM and the external case HAU. The display module DM may display the image IM in response to electrical signals. The display module DM may include a display area DA and a non-display area NDA defined adjacent to the display area DA.

The display area DA may be activated in response to electrical signals. The display area DA may be an area from which the image IM provided from the display substrate DP exits. The display area DA of the display module DM may overlap at least a portion of the transmission area TA. The image IM generated by the display area DA may be viewed from the outside through the transmission area TA.

The non-display area NDA may be defined adjacent to the display area DA. As an example, the non-display area NDA may surround the display area DA, however, it should not be limited thereto or thereby. According to an embodiment, the non-display area NDA may be defined in a variety of shapes. A driving circuit or a driving line to drive elements disposed in the display area DA, various signal lines to provide electrical signals to the elements, and pads may be disposed in the non-display area NDA. The non-display area NDA of the display module DM may overlap at least a portion of the bezel area BA. Components of the display module DM, which may be disposed in the non-display area NDA, may be prevented from being viewed from the outside by the bezel area BA.

The display substrate DP may be provided in the form of a panel and may be referred to as a display panel. The display substrate DP according to an embodiment may be a light-emitting type display panel, however, it should not be particularly limited. For instance, the display substrate DP may be an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot and/or a quantum rod. Hereinafter, the organic light emitting display panel will be described as a representative example of the display substrate DP.

The light control substrate LCM may be disposed on the display substrate DP. The light control substrate LCM may be coupled to the display substrate DP by a coupling process after being provided on the display substrate DP. The display substrate DP that may be formed under the display module DM may be defined as a first substrate, and the light control substrate LCM that may be coupled to the first substrate may be defined as a second substrate.

The light control substrate LCM may selectively convert a wavelength of the light provided from the display substrate DP or may transmit the light provided from the display substrate DP. The light control substrate LCM may prevent the light, which may be incident into the display device DD from the outside of the display device DD, from being reflected.

The external case HAU may be disposed under the display module DM and may accommodate the display module DM. The external case HAU may include a material with a relatively high strength. The external case HAU may absorb impacts applied thereto from the outside and may prevent a foreign substance and moisture from entering the display module DM, and thus, the display module DM may be protected by the external case HAU. According to an embodiment, the external case HAU may be provided in a form obtained by coupling multiple accommodating members.

The display device DD may further include an input sensing module that obtains coordinate information of the external input applied thereto from the outside of the display device DD. The input sensing module of the display device DD may be driven in various ways, such as a capacitive method, a resistive method, an infrared ray method, a pressure method, or the like, however, it should not be particularly limited.

The input sensing module may be disposed on the display module DM. The input sensing module may be disposed directly on the display module DM through successive processes or may be attached to the display module DM by an adhesive layer after being manufactured separately from the display module DM. The input sensing module may be disposed between components of the display module DM. As an example, the input sensing module may be disposed between the display substrate DP and the light control substrate LCM.

The display device DD may further include an electronic module including a variety of functional modules to drive the display module DM, a power supply module supplying a power required for an overall operation of the display device DD, and a bracket coupled to the display module DM and/or the external case HAU to divide an inner space of the display device DD.

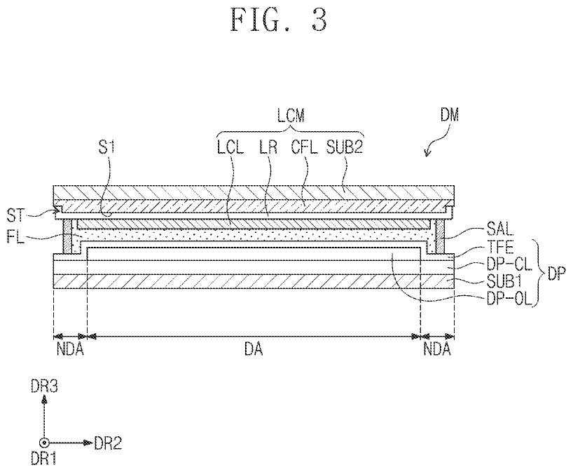

FIG. 3 is a schematic cross-sectional view of the display module DM according to an embodiment of the disclosure. Referring to FIG. 3, the display module DM may include the display substrate DP, the light control substrate LCM, a sealing member SAL and a filling member FL. The sealing member SAL and the filling member FL may be disposed between the display substrate DP and the light control substrate LCM. Descriptions of the display substrate DP and the light control substrate LCM may be the same as the details thereof described above.

Referring to FIG. 3, the display substrate DP may include a lower substrate SUB1, a circuit layer DP-CL, a light emitting element layer DP-OL, and an encapsulation layer TFE.

The lower substrate SUB1 may include a glass substrate, a polymer substrate, and/or an organic/inorganic composite material substrate. The lower substrate SUB1 may include an upper surface and a lower surface, which may be substantially parallel to each of the first direction DR1 and the second direction DR2. The lower substrate SUB1 may include a display area DA and a non-display area NDA and may provide a base surface on which components of the display substrate DP may be stacked. The circuit layer DP-CL, the light emitting element layer DP-OL, and the encapsulation layer TFE may be sequentially stacked on an upper surface of the lower substrate SUB1 in the third direction DR3.

The light emitting element layer DP-OL may include light emitting elements disposed in the display area DA. The circuit layer DP-CL may be disposed between the light emitting element layer DP-OL and the lower substrate SUB1 and may include driving elements, the signal lines, and the pads, which may be connected to the light emitting elements. The light emitting elements of the light emitting element layer DP-OL may provide a source light (or a first light) to the light control substrate LCM in the display area DA.

The encapsulation layer TFE may be disposed on the light emitting element layer DP-OL and may encapsulate the light emitting elements. The encapsulation layer TFE may include multiple thin films. The thin films of the encapsulation layer TFE may be disposed to improve an optical efficiency of the light emitting elements or to protect the light emitting elements.

Referring to FIG. 3, the light control substrate LCM may include an upper substrate SUB2, a color filter layer CFL, a low refractive index layer LR, and a light conversion layer LCL.

The upper substrate SUB2 may include a glass substrate, a polymer substrate, and/or an organic/inorganic composite material substrate. The upper substrate SUB2 may include a front surface and a rear surface, which may be substantially parallel to each of the first direction DR1 and the second direction DR2. The rear surface of the upper substrate SUB2 may face the upper surface of the lower substrate SUB1. The upper substrate SUB2 may provide a base surface on which components of the light control substrate LCM may be stacked. The color filter layer CFL, the low refractive index layer LR, and the light conversion layer LCL may be sequentially stacked on the rear surface of the upper substrate SUB2 in the third direction DR3.

The light conversion layer LCL may be disposed to overlap the display area DA and may include light conversion portions that convert an optical property of the source light provided from the light emitting element. The light conversion layer LCL may selectively transmit the source light or may selectively convert a wavelength of the source light. A portion of the light conversion layer LCL may overlap the non-display area NDA.

The color filter layer CFL may be disposed to overlap the display area DA and may filter lights exiting from the light conversion layer LCL. The color filter layer CFL may absorb lights exiting from the light conversion layer LCL without being converted by the light conversion layer LCL and thus may prevent a color purity of the display device DD (refer to FIG. 1) from being lowered. The color filter layer CFL may include color filters that display the same colors as those of the pixels. Accordingly, the color filter layer CFL may filter the external light to have the same color as the pixels and may reduce a reflectance of the display device DD (refer to FIG. 1) with respect to the external light.

The color filter layer CFL may be disposed to allow a portion thereof to overlap the non-display area NDA. The color filter layer CFL may include the color filters arranged in the non-display area NDA to overlap each other and may absorb the light exiting from or reflected by the non-display area NDA.

The color filter layer CFL may include a first surface S1 facing the display substrate DP. The first surface S1 of the color filter layer CFL may have a step difference ST in the non-display area NDA. The step difference ST may be formed by a difference in height between edges of the color filters included in the color filter layer CFL.

The low refractive index layer LR may be disposed between the light conversion layer LCL and the color filter layer CFL. The low refractive index layer LR may have a relatively lower refractive index than that of the light conversion portion of the light conversion layer LCL. The low refractive index layer LR may improve the light emitting efficiency of the display device DD (refer to FIG. 1) through the recycling of light using the refractive index.

The low refractive index layer LR may cover the first surface S1 of the color filter layer CFL. A portion of the low refractive index layer LR may be disposed on the step difference ST of the color filter layer CFL. The low refractive index layer LR overlapping the step difference ST may have a thickness different from that of the low refractive index layer LR disposed in the display area DA. The low refractive index layer LR overlapping the step difference ST may have a relatively small thickness or may include multiple intermittent portions, and thus, the inflow path of moisture or gas through the low refractive index layer LR disposed on the non-display area NDA may be blocked. This will be described in detail later.

The sealing member SAL may be disposed between the display substrate DP and the light control substrate LCM, and the display substrate DP may be coupled to the light control substrate LCM by the sealing member SAL. The sealing member SAL may be disposed to overlap the non-display area NDA. The display substrate DP and the light control substrate LCM may be formed through separate processes, and the display module DM may be manufactured by coupling the display substrate DP to the light control substrate LCM using the sealing member SAL. The sealing member SAL may include an ultraviolet-ray curable material. However, a material for the sealing member SAL should not be limited thereto or thereby.

The filling member FL may be disposed between the display substrate DP and the light control substrate LCM and may be filled in an empty space between the display substrate DP and the light control substrate LCM in the display area DA. According to an embodiment, the filling member FL may be disposed between the encapsulation layer TFE of the display substrate DP and the light conversion layer LCL of the light control substrate LCM. The filling member FL may include a silicon, epoxy, or acrylic-based heat curable material, however, a material for the filling member FL should not be limited thereto or thereby.

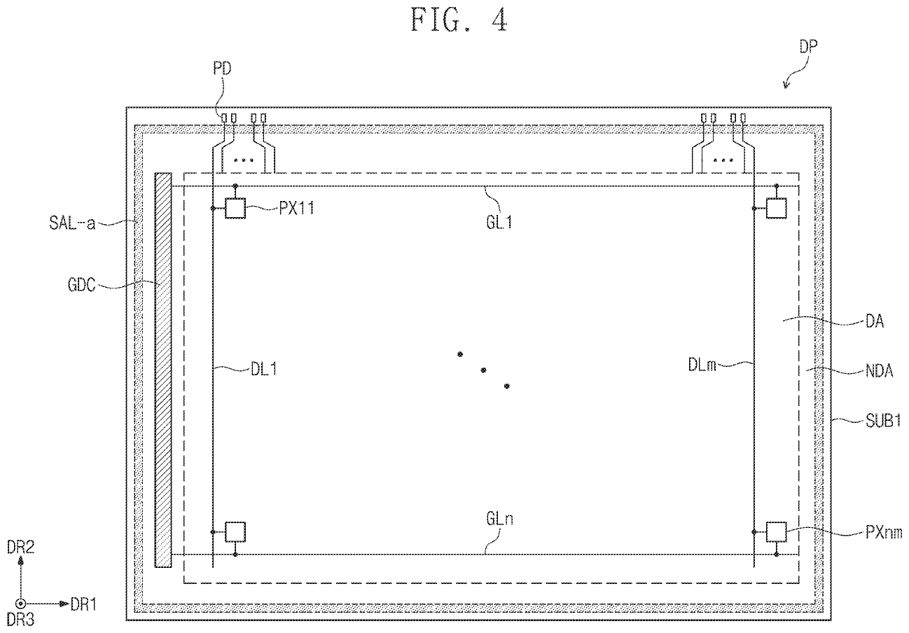

FIG. 4 is a schematic plan view of the display substrate DP according to an embodiment of the disclosure. FIG. 4 schematically shows components of the display substrate DP when viewed in the third direction DR3.

Referring to FIG. 4, the lower substrate SUB1 of the display substrate DP may include the display area DA and the non-display area NDA. The display substrate DP may include pixels PX11 to PXnm disposed in the display area DA and signal lines GL1 to GLn and DL1 to DLm electrically connected to the pixels PX11 to PXnm. The display substrate DP may include the driving circuit GDC and the pads PD, which may be disposed in the non-display area NDA.

Each of the pixels PX11 to PXnm may include the light emitting element and a pixel driving circuit including transistors (e.g., a switching transistor, a driving transistor, etc.) connected to the light emitting element. Each of the pixels PX11 to PXnm may emit a light in response to an electrical signal applied thereto. FIG. 4 shows the pixels PX11 to PXnm arranged in a matrix form as a representative example, however, the arrangement of the pixels PX11 to PXnm should not be limited thereto or thereby.

The signal lines GL1 to GLn and DL1 to DLm may include gate lines GL1 to GLn and data lines DL1 to DLm. Each of the pixels PX11 to PXnm may be connected to a corresponding gate line of the gate lines GL1 to GLn and a corresponding data line of the data lines DL1 to DLm. More types of signal lines may be provided in the display substrate DP depending on the configuration of the pixel driving circuit of the pixels PX11 to PXnm.

The driving circuit GDC may include a gate driving circuit. The gate driving circuit may generate the gate signals and may sequentially output the gate signals to the gate lines GL1 to GLn. The gate driving circuit may further output another control signal to the pixel driving circuit of the pixels PX11 to PXnm.

The pads PD may be arranged in the non-display area NDA along one direction. The pads PD may be connected to a circuit board. Each of the pads PD may be connected to a corresponding signal line among the signal lines GL1 to GLn and DL1 to DLm and may be connected to a corresponding pixel via the signal line. The pads PD may be provided integrally with the signal lines GL1 to GLn and DL1 to DLm, however, they should not be limited thereto or thereby. According to an embodiment, the pads PD may be disposed on a different layer from the signal lines GL1 to GLn and DL1 to DLm and may be connected to the signal lines GL1 to GLn and DL1 to DLm via a contact hole.

FIG. 4 shows a sealing member disposing area SAL-a corresponding to an area in which the sealing member SAL (refer to FIG. 3) may be disposed in a plan view as a representative example. The sealing member disposing area SAL-a may overlap the non-display area NDA and may correspond to a portion of the non-display area NDA. The sealing member disposing area SAL-a may be adjacent to an edge of the display substrate DP and may extend along a direction in which the edge of the display substrate DP extends. The sealing member disposing area SAL-a may surround the display area DA in a plan view. According to an embodiment, the sealing member disposing area SAL-a may be disposed outside an area where the driving circuit GDC may be disposed.

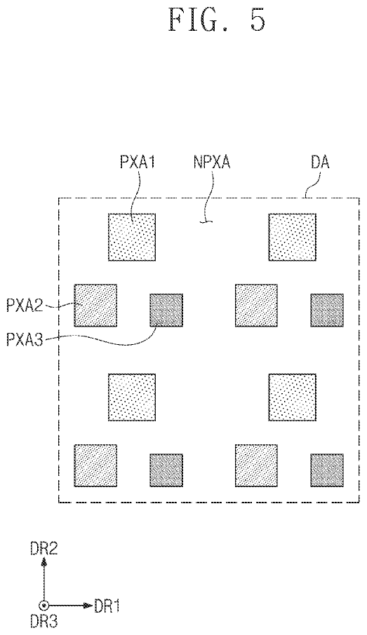

FIG. 5 is an enlarged schematic plan view of the display substrate DP (refer to FIG. 4) according to an embodiment of the disclosure. FIG. 5 is an enlarged plan view of a portion corresponding to the display area DA of the display substrate DP.

Referring to FIG. 5, the display area DA may include light emitting areas PXA1, PXA2, and PXA3 respectively corresponding to the light emitting elements and a non-light-emitting area NPXA surrounding the light emitting areas PXA1, PXA2, and PXA3. FIG. 5 shows an arrangement and a shape of the light emitting areas PXA1, PXA2, and PXA3.

The light emitting areas PXA1, PXA2, and PXA3 may respectively correspond to areas from which lights provided by the light emitting elements exit. The light emitting areas PXA1, PXA2, and PXA3 may include a first light emitting area PXA1, a second light emitting area PXA2, and a third light emitting area PXA3. The first, second, and third light emitting areas PXA1, PXA2, and PXA3 may be distinguished from each other depending on colors of lights traveling to the outside of the display device DD (refer to FIG. 1). The non-light-emitting area NPXA may define a boundary between the first, second, and third light emitting areas PXA1, PXA2, and PXA3 and may prevent colors of the lights emitted by the first, second, and third light emitting areas PXA1, PXA2, and PXA3 from being mixed.

Among the first, second, and third light emitting areas PXA1, PXA2, and PXA3, a light emitting area may provide a first color light corresponding to the source light provided by the light emitting element, another light emitting area may provide a second color light different from the first color light, and another light emitting area may provide a third color light different from the first color light and the second color light. As an example, the first color light may be a blue light, the second color light may be a red light, and the third color light may be a green light. However, the color lights should not be limited thereto or thereby.

The first, second, and third light emitting areas PXA1, PXA2, and PXA3 may be repeatedly arranged in an arrangement within the display area DA. Some of the first, second, and third light emitting areas PXA1, PXA2, and PXA3 may be arranged in a line along the first direction DR1 to form a row and may be arranged in a line along the second direction DR2 to form a column.

The first, second, and third light emitting areas PXA1, PXA2, and PXA3 may have a variety of shapes in a plan view. As an example, each of the first, second, and third light emitting areas PXA1, PXA2, and PXA3 may have a quadrangular shape as shown in FIG. 5, however, it should not be limited thereto or thereby. According to an embodiment, each of the first, second, and third light emitting areas PXA1, PXA2, and PXA3 may have a polygonal shape, a circular shape, an oval shape, or an irregular shape.

The first, second, and third light emitting areas PXA1, PXA2, and PXA3 may have substantially the same shape as each other in a plan view, however, they should not be limited thereto or thereby. According to an embodiment, at least two of the first, second, and third light emitting areas PXA1, PXA2, and PXA3 may have different shapes from each other.

At least two of the first, second, and third light emitting areas PXA1, PXA2, and PXA3 may have different sizes from each other in a plan view. However, according to an embodiment, the first, second, and third light emitting areas PXA1, PXA2, and PXA3 may have substantially the same size as each other.

The sizes of the first, second, and third light emitting areas PXA1, PXA2, and PXA3 may be determined depending on the colors of the light. As an example, among primary colors, the light emitting area emitting the green light may have the largest size, and the light emitting area emitting the blue light may have the smallest size. However, the disclosure should not be limited thereto or thereby, and the sizes of the first, second, and third light emitting areas PXA1, PXA2, and PXA3 may be changed depending on the structure of the display substrate DP. Hereinafter, the arrangement of the first, second, and third light emitting areas PXA1, PXA2, and PXA3 will be described in detail with reference to FIG. 5.

According to an embodiment, the first, second, and third light emitting areas PXA1, PXA2, and PXA3 may have the same shape but different sizes in a plan view. Referring to FIG. 5, the first, second, and third light emitting areas PXA1, PXA2, and PXA3 may have a quadrangular shape and may have different sizes in a plan view. FIG. 5 shows the first, second, and third light emitting areas PXA1, PXA2, and PXA3, each of which has the quadrangular shape with a right-angled corner as a representative example. However, the disclosure should not be limited thereto or thereby, and according to an embodiment, each of the first, second, and third light emitting areas PXA1, PXA2, and PXA3 may have a quadrangular shape with a rounded corner.

Multiple of the first, second, and third light emitting areas PXA1, PXA2, and PXA3 may be provided, and the first, second, and third light emitting areas PXA1, PXA2, and PXA3 may be arranged in an arrangement. The first light emitting areas PXA1 arranged in the first direction DR1 may be defined as a first group, and the second light emitting areas PXA2 and the third light emitting areas PXA3 arranged in the first direction DR1 may be defined as a second group. In the second group, the second light emitting areas PXA2 and the third light emitting areas PXA3 may be alternately arranged with each other in the first direction DR1.

Multiple first groups including the first light emitting areas PXA1 may be provided, and the first groups may be arranged in the second direction DR2. Similarly, multiple second groups including the second light emitting areas PXA2 and the third light emitting areas PXA3 may be provided, and the second groups may be arranged in the second direction DR2. As shown in FIG. 5, the first groups may be alternately arranged with the second groups in the second direction DR2.

However, the arrangement of the first, second, and third light emitting areas PXA1, PXA2, and PXA3 shown in FIG. 5 is merely an example, and the disclosure should not be limited thereto or thereby. According to an embodiment, the light emitting areas may be arranged in various ways according to the design of the display device DD. For example, the shape, size, and arrangement of the light emitting areas may be designed in various ways according to the light emitting efficiency of the lights depending on the colors and should not be limited to those shown in FIG. 5.

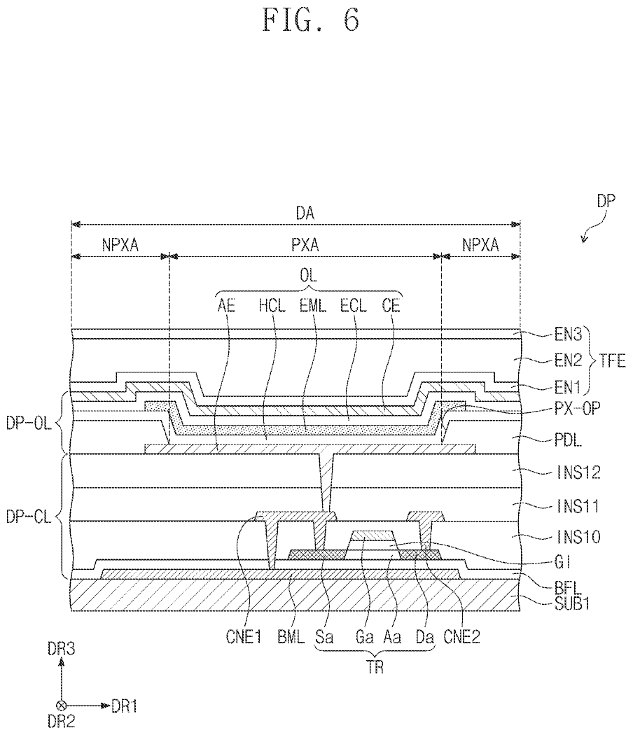

FIG. 6 is a schematic cross-sectional view of the display substrate DP according to an embodiment of the disclosure. Each of the pixels of the display substrate DP may have an equivalent circuit including transistors, at least one capacitor, and a light emitting element, and the equivalent circuit of the pixel may be changed in various ways. FIG. 6 shows a cross-section of a transistor TR and a light emitting element OL included in the pixel and corresponding to a light emitting area PXA. The light emitting area PXA shown in FIG. 6 may correspond to one of the first, second, and third light emitting areas PXA1, PXA2, and PXA3 shown in FIG. 5.

Referring to FIG. 6, the display substrate DP may include the lower substrate SUB1, the circuit layer DP-CL, the light emitting element layer DP-OL, and the encapsulation layer TFE, and descriptions of each component may be the same as the details thereof described above.

The display substrate DP may include an insulating layer, a semiconductor pattern, a conductive pattern, and a signal line. The insulating layer, a semiconductor layer, and a conductive layer may be formed on the lower substrate SUB1 by a coating or depositing process in a manufacturing process of the display substrate DP. The insulating layer, the semiconductor layer, and the conductive layer may be selectively patterned through several photolithography processes, and thus, the semiconductor pattern, the conductive pattern, and the signal line, which may be included in the display substrate DP, may be formed.

The lower substrate SUB1 may provide the base surface on which the circuit layer DP-CL may be disposed. The lower substrate SUB1 may have a single-layer or multi-layer structure. As an example, the lower substrate SUB1 having the multi-layer structure may include synthetic resin layers and at least one inorganic layer disposed between the synthetic resin layers or may include a glass substrate and a synthetic resin disposed on the glass substrate. However, the lower substrate SUB1 should not be limited thereto or thereby.

The synthetic resin layer included in the lower substrate SUB1 may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, a perylene-based resin, and a polyimide-based resin, however, the synthetic resin layer should not be limited thereto or thereby.

The circuit layer DP-CL may be disposed on the lower substrate SUB1. The circuit layer DP-CL may include at least one insulating layer, a conductive pattern, and a semiconductor pattern. A stack structure of the circuit layer DP-CL may be changed in various ways depending on the process of manufacturing the circuit layer DP-CL or the configuration of the elements included in the pixel. FIG. 6 shows the stack structure of the circuit layer DP-CL as a representative example. However, the disclosure should not be particularly limited as long as the circuit layer DP-CL includes driving elements to drive the pixels.

Referring to FIG. 6, the circuit layer DP-CL may include a light blocking pattern BML, the transistor TR, connection electrodes CNE1 and CNE2, an insulating pattern GI, a buffer layer BFL, and insulating layers INS10, INS11, and INS12.

The light blocking pattern BML may be disposed on the lower substrate SUB1. The light blocking pattern BML may prevent conductive patterns included in the circuit layer DP-CL from being viewed due to the external light. The light blocking pattern BML may overlap the transistor TR. The light blocking pattern BML may prevent the semiconductor pattern included in the transistor TR from being damaged due to the external light.

The buffer layer BFL may be disposed on the lower substrate SUB1 to cover the light blocking pattern BML. The buffer layer BFL may be provided with a contact hole defined therethrough to expose a portion of the light blocking pattern BML. The buffer layer BFL may increase an adhesion between the lower substrate SUB1 and the semiconductor pattern of the transistor TR.

The buffer layer BFL may include an inorganic material. As an example, the buffer layer BFL may include at least one of aluminum oxide, titanium oxide, silicon oxide, silicon nitride, silicon oxynitride, zirconium oxide, and hafnium oxide. However, materials for the buffer layer BFL should not be limited thereto or thereby.

The transistor TR may be disposed on the buffer layer BFL. The transistor TR may include the semiconductor pattern. The semiconductor pattern of the transistor TR may be arranged in a rule according to the equivalent circuit of the pixel. The semiconductor pattern may include polysilicon, however, it should not be limited thereto or thereby. The semiconductor pattern may include amorphous silicon, crystalline silicon, and/or polycrystalline silicon.

A source area Sa, a drain area Da, and a channel area Aa of the transistor TR may be formed from the semiconductor pattern. The semiconductor pattern may include areas distinguished from each other depending on a conductivity. As an example, the semiconductor pattern may have different electrical properties depending on whether it is doped or not or whether a metal oxide is reduced. A portion of the semiconductor pattern, which has a relatively high conductivity, may serve as an electrode or a signal line and may correspond to the source area Sa and the drain area Da of the transistor TR. A non-doped portion or a non-reduced portion with a relatively low conductivity may correspond to the channel area Aa (or an active area) of the transistor TR.

The insulating pattern GI may be disposed on the semiconductor pattern of the transistor TR. The insulating pattern GI may be formed by forming an insulating layer on the semiconductor pattern of the transistor TR and patterning the insulating layer. A gate electrode Ga of the transistor TR may be disposed on the insulating pattern GI. The gate electrode Ga may serve as a mask in a process of forming the insulating pattern GI. The gate electrode Ga may overlap the channel area Aa of the transistor TR and may be spaced apart from the semiconductor pattern of the transistor TR.

The insulating layers INS10, INS11, and INS12 may be disposed on the buffer layer BFL. Each of the insulating layers INS10, INS11, and INS12 may include an inorganic layer or an organic layer. As an example, the inorganic layer may include at least one of aluminum oxide, titanium oxide, silicon oxide, silicon nitride, silicon oxynitride, zirconium oxide, and hafnium oxide. The organic layer may include a phenolic-based polymer, an acrylic-based polymer, an imide-based polymer, an aryl ether-based polymer, an amide-based polymer, a fluorine-based polymer, a p-xylene-based polymer, a vinyl alcohol-based polymer, or blends thereof. However, the material for the insulating layer should not be limited thereto or thereby.

A first insulating layer INS10 may be disposed on the buffer layer BFL. The first insulating layer INS10 may cover the gate electrode Ga. The connection electrodes CNE1 and CNE2 may be disposed on the first insulating layer INS10.

The connection electrodes CNE1 and CNE2 may include a first connection electrode CNE1 and a second connection electrode CNE2. The first connection electrode CNE1 may be connected to the source area Sa of the transistor TR via a contact hole defined through the first insulating layer INS10. The first connection electrode CNE1 may be connected to the light blocking pattern BML via a contact hole defined through the first insulating layer INS10 and the buffer layer BFL. The second connection electrode CNE2 may be connected to the drain area Da of the transistor TR via a contact hole defined through the first insulating layer INS10. The second connection electrode CNE2 may extend to be connected to another transistor or line in a plan view.

A second insulating layer INS11 and a third insulating layer INS12 may be disposed on the first insulating layer INS10 to cover the connection electrodes CNE1 and CNE2. The first connection electrode CNE1 may be connected to a first electrode AE of the light emitting element OL disposed on the third insulating layer INS12 via a contact hole defined through the second insulating layer INS11 and the third insulating layer INS12.

The third insulating layer INS12 may include an organic layer. The third insulating layer INS12 may provide a flat upper surface to components disposed thereon, however, the disclosure should not be limited thereto or thereby.

The light emitting element layer DP-OL may be disposed on the circuit layer DP-CL. The light emitting element layer DP-OL may include the light emitting element OL and a pixel definition layer PDL. FIG. 6 shows one light emitting element OL as a representative example. However, according to an embodiment, the light emitting element layer DP-OL may include multiple light emitting elements OL.

The light emitting element layer DP-OL may include the light emitting area PXA corresponding to the light emitting element OL and the non-light-emitting area NPXA surrounding the light emitting area PXA in the display area DA. The light emitting element OL may include the first electrode AE, a hole control layer HCL, a light emitting layer EML, an electron control layer ECL, and a second electrode CE.

The pixel definition layer PDL may be disposed on the third insulating layer INS12. The pixel definition layer PDL may be provided with a light emitting opening PX-OP defined therethrough to expose at least a portion of the first electrode AE. The pixel definition layer PDL may cover a portion of an upper surface of the first electrode AE. In an embodiment, the portion of the first electrode AE exposed through the light emitting opening PX-OP may correspond to the light emitting area PXA. The area in which the pixel definition layer PDL may be disposed may correspond to the non-light-emitting area NPXA surrounding the light emitting area PXA.

The pixel definition layer PDL may include a polymer resin. As an example, the pixel definition layer PDL may include a polyacrylate-based resin or a polyimide-based resin. The pixel definition layer PDL may further include an inorganic material in addition to the polymer resin. According to an embodiment, the pixel definition layer PDL may include an inorganic material. As an example, the pixel definition layer PDL may include silicon nitride (SiNₓ), silicon oxide (SiOₓ), and/or silicon oxynitride (SiOₓN_{y}).

The pixel definition layer PDL may include a light absorbing material. The pixel definition layer PDL may include a black coloring agent. The black coloring agent may include a black pigment or a black dye. The black coloring agent may include a metal material, such as carbon black, chrome, etc., or an oxide thereof. However, the pixel definition layer PDL should not be limited thereto or thereby.

The hole control layer HCL may be disposed on the first electrode AE and the pixel definition layer PDL. The hole control layer HCL may be commonly disposed over the pixels. The hole control layer HCL may overlap the light emitting area PXA and the non-light-emitting area NPXA. The hole control layer HCL may include at least one of a hole injection layer and a hole transport layer.

The light emitting layer EML may be disposed on the hole control layer HCL. The light emitting layer EML may be disposed in an area corresponding to the light emitting opening PX-OP of the pixel definition layer PDL. The light emitting layer EML may include an organic light emitting material, an inorganic light emitting material, a quantum dot, and/or a quantum rod. The light emitting layer EML may be provided in the form of light emitting pattern to be separately provided in each pixel, however, it should not be limited thereto or thereby. According to an embodiment, the light emitting layer EML may be provided as a common layer commonly disposed over the pixels. The light emitting layer EML may generate the first light as the source light. As an example, the first light may be the blue light, however, it should not be limited thereto or thereby.

According to an embodiment, the light emitting element OL may be a light emitting element having a tandem structure in which multiple light emitting layers may be disposed on the first electrode AE in the third direction DR3. The light emitting layers may generate lights having substantially the same colors as each other, however, they should not be limited thereto or thereby. According to an embodiment, some of the light emitting layers may generate lights having substantially the same colors, and other of the light emitting layers may generate lights having different colors. As an example, the light emitting element OL may include four light emitting layers, three light emitting layers among the four light emitting layers may generate the blue light, and one light emitting layer among the four light emitting layers may generate the green light. However, the light emitting layer EML of the light emitting element OL having the tandem structure should not be limited thereto or thereby. The light emitting element OL having the tandem structure may further include functional layers such as the hole control layer, the electron control layer, and a charge generation layer, which may be disposed between the light emitting layers.

The electron control layer ECL may be disposed on the light emitting layer EML. The electron control layer ECL may be commonly disposed over the pixels. The electron control layer ECL may overlap the light emitting area PXA and the non-light-emitting area NPXA. The electron control layer ECL may include at least one of an electron transport layer and an electron injection layer.

The second electrode CE may be disposed on the electron control layer ECL. The second electrode CE may be commonly disposed over the pixels. The second electrode CE may overlap the light emitting area PXA and the non-light-emitting area NPXA. A common voltage may be provided to the pixels via the second electrode CE.

A first voltage may be applied to the first electrode AE via the transistor TR, and the common voltage may be applied to the second electrode CE. Holes and electrons, which may be injected into the light emitting layer EML, may be recombined with each other to generate excitons. The light emitting element OL may emit the light in case that the excitons return to a ground state from an excited state.

The encapsulation layer TFE may be disposed on the light emitting element layer DP-OL and may encapsulate the light emitting element OL. The encapsulation layer TFE may include first, second, and third encapsulation layers EN1, EN2, and EN3. The first encapsulation layer EN1 may be disposed on the second electrode CE, and the second and third encapsulation layers EN2 and EN3 may be sequentially disposed on the first encapsulation layer EN1.

According to an embodiment, the first and third encapsulation layers EN1 and EN3 may include an inorganic layer, and the inorganic layer may protect the light emitting element layer DP-OL from moisture and/or oxygen. As an example, the inorganic layer may include at least one of aluminum oxide, titanium oxide, silicon oxide, silicon nitride, silicon oxynitride, zirconium oxide, and hafnium oxide, however, they should not be limited thereto or thereby.

The second encapsulation layer EN2 may include an organic layer, and the organic layer may protect the light emitting element layer DP-OL from a foreign substance such as dust particles. As an example, the organic layer may include an acrylic-based resin, however, the material of the organic layer should not be limited thereto or thereby.

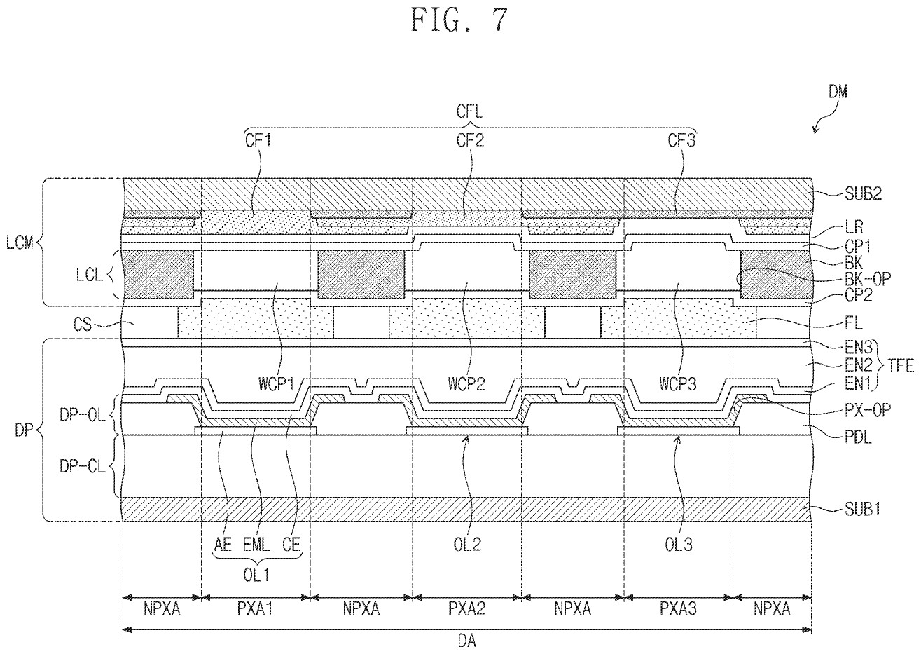

FIG. 7 is a schematic cross-sectional view of the display module DM according to an embodiment of the disclosure. FIG. 7 shows a cross-section of the display module DM corresponding to the first, second, and third light emitting areas PXA1, PXA2, and PXA3 in the display area DA. Descriptions of each component of the display module DM shown in FIG. 7 may be the same as the details thereof described above.

Referring to FIG. 7, the light emitting element layer DP-OL may include light emitting elements OL1, OL2, and OL3. Each of the light emitting elements OL1, OL2, and OL3 may include the first electrode AE, the light emitting layer EML, and the second electrode CE. Although not shown in FIG. 7, each of the light emitting elements OL1, OL2, and OL3 may further include the hole control layer HCL (refer to FIG. 6) and the electron control layer ECL (refer to FIG. 6).

The first electrodes AE of the light emitting elements OL1, OL2, and OL3 may be disposed on the circuit layer DP-CL and may be spaced apart from each other. The pixel definition layer PDL may be provided with light emitting openings PX-OP defined therethrough to expose portions of the first electrodes AE, respectively. The first electrodes AE of first, second, and third light emitting elements OL1, OL2, and OL3, which may be exposed through the light emitting openings PX-OP, may respectively correspond to the first, second, and third light emitting areas PXA1, PXA2, and PXA3.

The light emitting layers EML of the light emitting elements OL1, OL2, and OL3 may be disposed to respectively correspond to the light emitting openings PX-OP, however, they should not be limited thereto or thereby. According to an embodiment, the light emitting layers EML of the light emitting elements OL1, OL2, and OL3 may be provided integrally with each other.

The second electrodes CE of the light emitting elements OL1, OL2, and OL3 may be connected to each other and provided integrally with each other. The second electrode CE provided in an integral shape may overlap the first, second, and third light emitting areas PXA1, PXA2, and PXA3 and the non-light-emitting area NPXA.

The light control substrate LCM may include the upper substrate SUB2, the color filter layer CFL, the low refractive index layer LR, and the light conversion layer LCL, which may be disposed above the display substrate DP. The light control substrate LCM may further include a first capping layer CP1 disposed between the low refractive index layer LR and the light conversion layer LCL and a second capping layer CP2 disposed on the rear surface of the light conversion layer LCL.

The rear surface of the upper substrate SUB2 may face the upper surface of the lower substrate SUB1. Referring to FIG. 7, the color filter layer CFL, the low refractive index layer LR, the first capping layer CP1, the light conversion layer LCL, and the second capping layer CP2 may be sequentially arranged on the rear surface of the upper substrate SUB2 in a thickness direction of the display module DM.

The color filter layer CFL may include a first color filter CF1, a second color filter CF2, and a third color filter CF3. The first, second, and third color filters CF1, CF2, and CF3 may be patterned and disposed on the rear surface of the upper substrate SUB2 to overlap the first, second, and third light emitting areas PXA1, PXA2, and PXA3, respectively. In a process of manufacturing the light control substrate LCM, the third color filter CF3, the second color filter CF2, and the first color filter CF1 may be sequentially formed on the rear surface of the upper substrate SUB2.

The first, second, and third color filters CF1, CF2, and CF3 may be disposed to respectively correspond to the first, second, and third light emitting areas PXA1, PXA2, and PXA3 in a plan view. As an example, the first color filter CF1 may be disposed to overlap the first light emitting area PXA1, the second color filter CF2 may be disposed to overlap the second light emitting area PXA2, and the third color filter CF3 may be disposed to overlap the third light emitting area PXA3. The first, second, and third color filters CF1, CF2, and CF3 will be described in detail later.

The low refractive index layer LR may be disposed between the light conversion layer LCL and the color filter layer CFL. In the manufacturing process of the light control substrate LCM, the low refractive index layer LR may be disposed to cover the color filter layer CFL formed on the upper substrate SUB2. Accordingly, the low refractive index layer LR may be disposed between the display substrate DP and the color filter layer CFL and may cover the rear surface (or lower surface) of the color filter layer CFL, which faces the display substrate DP.

The low refractive index layer LR may have a refractive index smaller than a refractive index of each of a first light conversion portion WCP1, a second light conversion portion WCP2, and a transmission portion WCP3 of the light conversion layer LCL described later. As an example, the refractive index of the low refractive index layer LR may be equal to or greater than about 1.1 and equal to or smaller than about 1.5, particularly, equal to or greater than about 1.1 and equal to or smaller than about 1.35. However, the refractive index of the low refractive index layer LR should not be limited to the above-mentioned numerical examples. The low refractive index layer LR may include an organic layer with a relatively low refractive index (e.g., a low refractive index organic layer). The low refractive index layer LR may further include scattering particles dispersed in the organic layer.

The low refractive index layer LR disposed on the light conversion layer LCL may allow lights that may not be converted by the light conversion portions WCP1 and WCP2 to be incident into the light conversion portions WCP1 and WCP2 again using the refractive index. The lights incident into the light conversion portions WCP1 and WCP2 again by the low refractive index layer LR may be converted to lights of a specific wavelength in the light conversion portions WCP1 and WCP2. For example, the low refractive index layer LR may recirculate the light using the refractive index, and thus, a light emitting efficiency of the display device DD (refer to FIG. 1) may be improved.

The low refractive index layer LR may include a material with a high light transmittance. As an example, the low refractive index layer LR may have the light transmittance equal to or greater than about 90%. As the low refractive index layer LR has the high light transmittance, the light may travel to the front surface of the display module DM without being interfered after passing through the light conversion layer LCL.

The first capping layer CP1 may be disposed on a rear surface of the low refractive index layer LR facing the display substrate DP. The first capping layer CP1 may include an inorganic material. In the manufacturing process of the light control substrate LCM, the first capping layer CP1 may be disposed on the low refractive index layer LR and may cover the low refractive index layer LR. The first capping layer CP1 may prevent moisture or gas from entering the low refractive index layer LR. In the manufacturing process of the light control substrate LCM, the first capping layer CP1 may be provided as a base surface to form the light conversion layer LCL and may protect the light conversion layer LCL.

The second capping layer CP2 may be disposed on the rear surface (or the lower surface) of the light conversion layer LCL and may cover the light conversion layer LCL. The second capping layer CP2 may include an inorganic material. The second capping layer CP2 may prevent moisture or a foreign substance from entering the light conversion layer LCL. Due to the second capping layer CP2, the light conversion layer LCL may be prevented from being deteriorated by moisture.

However, a stack order of the components of the light control substrate LCM should not be limited to the stack structure shown in FIG. 7. As an example, the light control substrate LCM may include multiple low refractive index layers. A low refractive index layer may be disposed between the color filter layer CFL and the light conversion layer LCL, and another may be disposed on the rear surface of the light conversion layer LCL.

The light conversion layer LCL may include the first light conversion portion WCP1, the second light conversion portion WCP2, the transmission portion WCP3, and a bank portion BK. FIG. 7 shows a cross-section of one first light conversion portion WCP1, one second light conversion portion WCP2, and one transmission portion WCP3 as a representative example, however, multiple first light conversion portions WCP1, second light conversion portions WCP2, and transmission portions WCP3 may be provided in the display area DA.

The bank portion BK may be disposed to overlap the non-light-emitting area NPXA in a plan view. The bank portion BK may be provided with openings BK-OP defined therethrough to correspond to the first, second, and third light emitting areas PXA1, PXA2, and PXA3, respectively. The first light conversion portion WCP1, the second light conversion portion WCP2, and the transmission portion WCP3 may be disposed to correspond to the openings BK-OP of the bank portion BK, respectively. In the case where multiple first light conversion portions WCP1, second light conversion portions WCP2, and transmission portions WCP3 may be provided, the bank portion BK may surround the first light conversion portions WCP1, the second light conversion portions WCP2, and the transmission portions WCP3.

The bank portion BK may serve as a boundary between the first light conversion portion WCP1, the second light conversion portion WCP2, and the transmission portion WCP3 to prevent color mixture from occurring. The bank portion BK may include a material with a color. As an example, the bank portion BK may include a black dye or a black pigment.

The first light conversion portion WCP1, the second light conversion portion WCP2, and the transmission portion WCP3 may be disposed to respectively correspond to the first, second, and third light emitting areas PXA1, PXA2, and PXA3. In detail, the first light conversion portion WCP1 may be disposed to overlap the first light emitting area PXA1, the second light conversion portion WCP2 may be disposed to overlap the second light emitting area PXA2, and the transmission portion WCP3 may be disposed to overlap the third light emitting area PXA3.

Each of the light emitting elements OL1, OL2, and OL3 may provide the source light (or the first light). The source light may be the blue light, however, it should not be limited thereto or thereby. According to an embodiment, the source light may correspond to a light provided by a structure in which light emitting layers emitting the blue light and at least one light emitting layer emitting the green light are stacked.

Each of the first light conversion portion WCP1 and the second light conversion portion WCP2 may include a base resin and quantum dots dispersed in the base resin. The quantum dots may convert a wavelength range of the source light provided by the light emitting elements OL1, OL2, and OL3. As an example, the first light conversion portion WCP1 may include first quantum dots that convert the first light provided by the first light emitting element OL1 to a second light having a wavelength range different from the wavelength range of the first light. The second light conversion portion WCP2 may include second quantum dots that convert the first light provided by the second light emitting element OL2 to a third light having a wavelength range different from the wavelength range of the first light. The wavelength range of the second light may be different from the wavelength range of the third light.

The first quantum dots of the first light conversion portion WCP1 may convert the source light provided by the first light emitting element OL1 to the green light. The second quantum dots of the second light conversion portion WCP2 may convert the source light provided by the second light emitting element OL2 to the red light. The quantum dots included in the first and second light conversion portions WCP1 and WCP2 will be described in detail later.

The transmission portion WCP3 may include a base resin. The transmission portion WCP3 may transmit the source light provided by the third light emitting element OL3. As an example, the third light emitting element OL3 may provide the blue light, and the blue light may travel to the front surface of the display module DM after passing through the transmission portion WCP3.

Accordingly, the display module DM may emit the green light through the first light emitting area PXA1, may emit the red light through the second light emitting area PXA2, and may emit the blue light through the third light emitting area PXA3. The display module DM may display an image through the display area DA using the first, second, and third light emitting areas PXA1, PXA2, and PXA3 respectively displaying green, red, and blue colors. However, the colors of the lights exiting through the light emitting areas PXA1, PXA2, and PXA3 should not be limited thereto or thereby.

The transmission portion WCP3 may further include scattering particles dispersed in the base resin. The scattering particles of the transmission portion WCP3 may scatter the light incident thereto in several directions. According to an embodiment, the first and second light conversion portions WCP1 and WCP2 may further include scattering particles dispersed in the base resin.

The scattering particles may scatter the light exiting through the light conversion portions WCP1 and WCP2 or the transmission portion WCP3 in several directions. The scattering particles may be particles having a relatively large density or specific gravity. The scattering particles may include titanium oxide (TiO₂) or silica-based nanoparticles. Since the light conversion portions WCP1 and WCP2 include the scattering particles, a light conversion efficiency of the quantum dots in the light conversion portions WCP1 and WCP2 may be improved.

Each of the first, second, and third color filters CF1, CF2, and CF3 may include a base resin and a pigment or dye dispersed in the base resin. Each of the first, second, and third color filters CF1, CF2, and CF3 may transmit a light having a specific wavelength range and may absorb most of the light having a wavelength range outside the specific wavelength range. As an example, one of the first, second, and third color filters CF1, CF2, and CF3 may include a red color filter, another of the first, second, and third color filters CF1, CF2, and CF3 may include a green color filter, and another of the first, second, and third color filters CF1, CF2, and CF3 may include a blue color filter.

The red color filter may transmit the red light and may absorb most of the green and blue lights. The green color filter may transmit the green light and may absorb most of the red and blue lights. The blue color filter may transmit the blue light and may absorb most of the red and green lights. However, the colors of the color filters should not be limited thereto or thereby.

The first color filter CF1 may be disposed on the first light conversion portion WCP1. The first color filter may transmit the second light provided from the first light conversion portion WCP1. As an example, the first light conversion portion WCP1 may convert the blue light provided from the first light emitting element OL1 to the green light, and the first color filter CF1 may transmit the green light provided from the first light conversion portion WCP1. The first color filter CF1 may absorb the red and blue lights incident thereto. Accordingly, the first light that may not be converted by the first light conversion portion WCP1 and may be incident into the first color filter CF1 may be absorbed by the first color filter CF1, and thus, a color purity may be prevented from being lowered in the first light emitting area PXA1.

The second color filter CF2 may be disposed on the second light conversion portion WCP2 and may transmit the third light provided from the second light conversion portion WCP2. As an example, the second light conversion portion WCP2 may convert the blue light provided from the second light emitting element OL2 to the red light, and the second color filter CF2 may transmit the red light provided from the second light conversion portion WCP2. The second color filter CF2 may absorb the green and blue lights incident thereto. Accordingly, the first light that may not be converted by the second light conversion portion WCP2 and may be incident into the second color filter CF2 may be absorbed by the second color filter CF2, and thus, a color purity may be prevented from being lowered in the second light emitting area PXA2.

The third color filter CF3 may be disposed on the transmission portion WCP3 and may transmit the first light exiting from the transmission portion WCP3. As an example, the transmission portion WCP3 may transmit the blue light provided from the third light emitting element OL3, and the blue light may pass through the third color filter CF3 after passing through the transmission portion WCP3.

The external light such as a natural light may be incident to the display substrate DP from the outside of the display module DM. The external light may include the red light, the green light, and the blue light. In a case where the display module DM does not include the color filter layer CFL, the external light incident into the display substrate DP may be reflected by the conductive patterns, such as signal lines, electrodes, etc., in the display substrate DP and may be provided to the user, and thus, the user may perceive the external light as a reflected light.

The first, second, and third color filters CF1, CF2, and CF3 may prevent the external light from being reflected. The first color filter CF1 transmitting the second light may absorb lights of external lights provided from the outside, which correspond to the wavelength ranges of the first light and the third light. As an example, the first color filter CF1 may be the green color filter that absorbs the lights of the external lights, which correspond to the red and blue lights and filter the lights to the green light. On the same principle, the second color filter CF2 may be the red color filter that absorbs the lights of the external lights, which correspond to the green and blue lights and filter the lights to the red light. The third color filter CF3 may be the blue color filter that absorbs the lights of the external lights, which correspond to the red and green lights and filter the lights to the blue light.

The first, second, and third color filters CF1, CF2, and CF3 may overlap each other in the non-light-emitting area NPXA. For example, the first, second, and third color filters CF1, CF2, and CF3 may be disposed to overlap each other along the thickness direction of the display module DM on the area in which the bank portion BK may be disposed. The first, second, and third color filters CF1, CF2, and CF3 disposed to overlap each other may block the light traveling through the non-light-emitting area NPXA and may prevent the color mixture from occurring between the first, second, and third light emitting areas PXA1, PXA2, and PXA3.

The color filter layer CFL may further include a barrier wall disposed in the non-light-emitting area NPXA. The barrier wall may surround the first, second, and third color filters CF1, CF2, and CF3 respectively overlapping the light emitting areas PXA1, PXA2, and PXA3 and may define a boundary between the first, second, and third color filters CF1, CF2, and CF3. The barrier wall of the color filter layer CFL may include a material with a color, such as a black pigment or a black dye. The barrier wall of the color filter layer CFL may absorb the light to prevent the color mixture from occurring between the light emitting areas PXA1, PXA2, and PXA3.

A core of the quantum dots included in the first light conversion portion WCP1 and the second light conversion portion WCP2 may be selected from a group II-VI compound, a group III-VI compound, a group compound, a group III-V compound, a group IV-VI compound, a group IV element, a group IV compound, and a combination thereof.

The group II-VI compound may be selected from a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-VI compound may include a binary compound of In₂S₃ or In₂Se₃, a ternary compound of InGaS₃ or InGaSe₃, or an arbitrary combination thereof.

The group compound may include a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound of AgInGaS₂, CuInGaS₂, or the like.

The group III-V compound may be selected from a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AINAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The group III-V compound may further include a group II metal. For instance, InZnP may be selected as a group III-II-V compound.

The group IV-VI compound may be selected from a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The group IV element may be selected from the group consisting of Si, Ge, and a mixture thereof. The group IV compound may be a binary compound selected from the group consisting of SiC, SiGe, and a mixture thereof.

The binary compound, the ternary compound, or the quaternary compound may exist in the particles at a uniform concentration or may exist in the same particle after being divided into multiple portions having different concentrations.

The quantum dots may have a core/shell structure including a core and a shell surrounding the core. The quantum dots may have a core/shell structure in which one quantum dot surrounds another quantum dot. In the core/shell structure, the concentration of elements existing in the shell may have a concentration gradient that may be lowered as the distance from a center of the quantum dot decreases in an interface between the core and the shell.

The quantum dot may have a core-shell structure that includes the above-mentioned nanocrystal. The shell of the quantum dot may serve as a protective layer to prevent chemical modification of the core and to maintain semiconductor properties and/or may serve as a charging layer to impart electrophoretic properties to the quantum dot. The shell may have a single-layer or multi-layer structure. The shell of the quantum dots may include metal oxides, non-metal oxides, semiconductor compounds, or combinations thereof as its representative example.

The metal oxides or non-metal oxides may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound, such as MgAl₂O₄, CoFe₂O₄, NiFe₂O₄, and/or CoMn₂O₄, however, they should not be limited thereto or thereby.

The semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb, however, they should not be limited thereto or thereby.

The quantum dots may have a full width of half maximum (FWHM) of the light emission wavelength spectrum of about 45 nm or less, in an embodiment about 40 nm or less, and in another embodiment about 30 nm or less. The color purity and the color reproducibility may be improved within this range. Since the light emitted through the quantum dots may be emitted in all directions, an optical viewing angle may be improved.

The shape of the quantum dots may have a shape commonly used in the art, however, it should not be particularly limited. In more detail, spherical, pyramidal, multi-arm, or cubic nanoparticles, nanotubes, nanowires, nanofibers, nanoplatelets, or the like may be applied to the quantum dots.

The quantum dots may control the color of the emitted light depending on a particle size thereof, and accordingly, the quantum dots may have various emission colors such as blue, red, and green colors. In a case where the light emitting layer EML includes the quantum dots, descriptions of the quantum dots included in the light emitting layer EML may be the same as the details thereof described above.

The circuit layer DP-CL, the light emitting element layer DP-OL, and the encapsulation layer TFE may be sequentially stacked on the upper surface of the lower substrate SUB1 along the thickness direction, and the display substrate DP may be formed. The color filter layer CFL, the low refractive index layer LR, the first capping layer CP1, the light conversion layer LCL, and the second capping layer CP2 may be sequentially stacked on the rear surface of the upper substrate SUB2 along the thickness direction, and thus, the light control substrate LCM may be formed.

The display substrate DP and the light control substrate LCM may be provided to allow the upper surface of the lower substrate SUB1 to face the rear surface of the upper substrate SUB2, and the filling member FL may be provided between the display substrate DP and the light control substrate LCM. As an example, the filling member FL may be disposed between the encapsulation layer TFE and the light conversion layer LCL. The display substrate DP and the light control substrate LCM may be coupled to each other with the filling member FL interposed therebetween, and the space between the display substrate DP and the light control substrate LCM, which overlaps the display area DA, may be filled with the filling member FL.

The display module DM may further include a column spacer CS disposed between the display substrate DP and the light control substrate LCM. Multiple column spacers CS may be provided, and the column spacers CS may be disposed spaced apart from each other to correspond to the non-light-emitting area NPXA, and thus, the light emitting efficiency of the display substrate DP may not be lowered. The column spacers CS may overlap the bank portion BK in a plan view. The column spacers CS may support the display substrate DP and the light control substrate LCM such that the display substrate DP may be coupled to the light control substrate LCM in a flat state in a process of coupling the display substrate DP to the light control substrate LCM.

The column spacer CS may include an insulating material. As an example, the column spacer CS may include an organic material. According to an embodiment, the column spacer CS may further include a black material, and the column spacer CS and the bank portion BK may prevent the color mixture from occurring, however, the column spacer CS should not be limited thereto or thereby.

FIG. 7 shows the display module DM including the column spacer CS, however, according to an embodiment, the column spacer CS may be omitted.

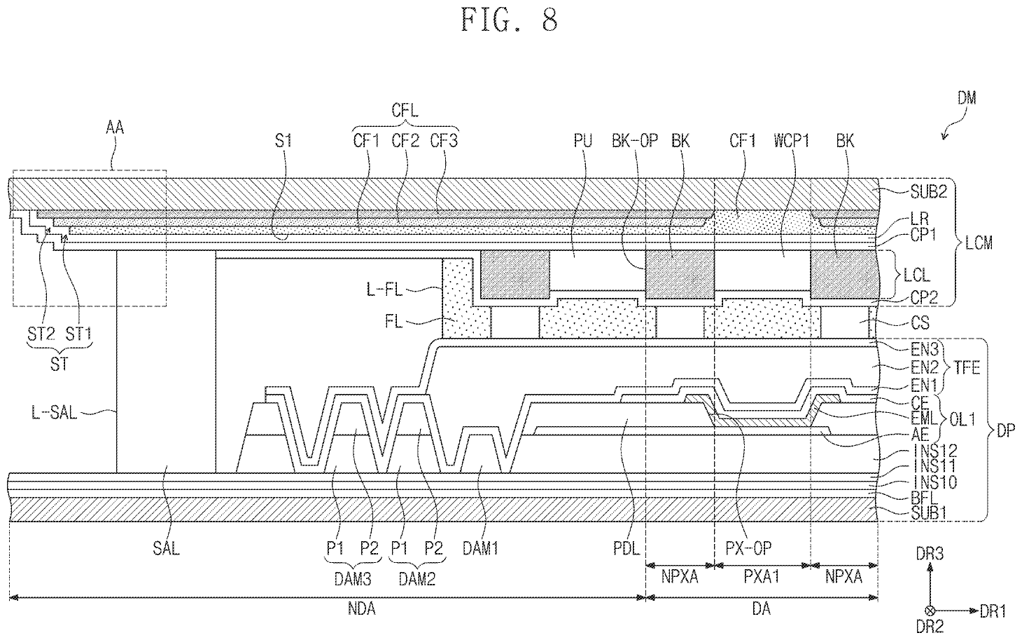

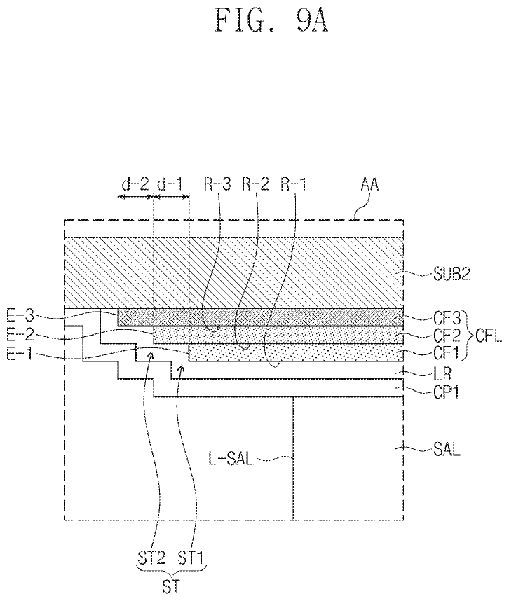

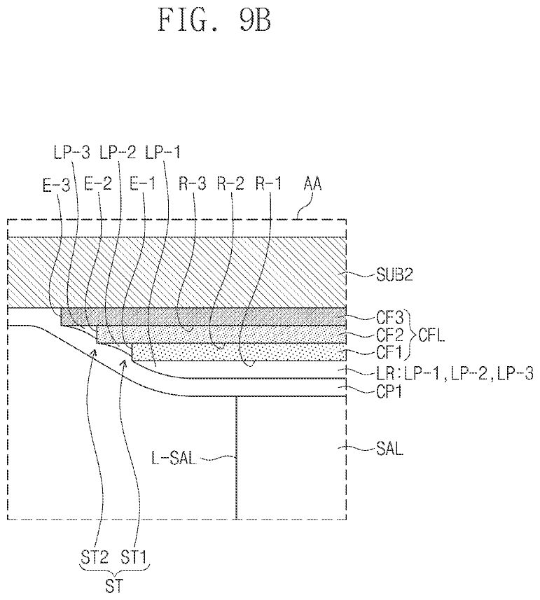

FIG. 8 is a schematic cross-sectional view of the display module DM according to an embodiment of the disclosure. FIGS. 9A and 9B are enlarged schematic cross-sectional views of display modules in area AA of FIG. 8 according to embodiments of the disclosure.

FIG. 8 shows a cross-section of the display module DM in the non-display area NDA and the display area DA adjacent to the non-display area NDA. FIG. 8 shows the first light emitting element OL1 and the first light conversion portion WCP1, which may be disposed adjacent to the non-display area NDA and corresponding to the first light emitting area PXA1. However, components disposed adjacent to the non-display area NDA should not be limited thereto or thereby. Descriptions of each component shown in FIG. 8 may be the same as the details thereof described above, and hereinafter, descriptions will be focused on components that are not explained.

Referring to FIG. 8, the buffer layer BFL, the first insulating layer INS10, and the second insulating layer INS11, which may be disposed on the upper surface of the lower substrate SUB1, may extend from the display area DA to the non-display area NDA.

The display substrate DP may include dams DAM1, DAM2, and DAM3 disposed in the non-display area NDA. The dams DAM1, DAM2, and DAM3 may be disposed on the lower substrate SUB1. The dams DAM1, DAM2, and DAM3 may be disposed on the second insulating layer INS11, however they should not be limited thereto or thereby.

The dams DAM1, DAM2, and DAM3 may include a first dam DAM1, a second dam DAM2, and a third dam DAM3 that may be disposed spaced apart from each other in a direction from the display area DA to the non-display area NDA. Among the dams DAM1, DAM2, and DAM3, the first dam DAM1 may be disposed closest to the display area DA, and the third dam DAM3 may be disposed farthest from the display area DA. However, the number of the dams DAM1, DAM2, and DAM3 should not be limited to three and may be more or less than three.

At least two of the dams DAM1, DAM2, and DAM3 may have different heights from each other in the third direction DR3. As an example, the height of the first dam DAM1 may be smaller than the height of each of the second dam DAM2 and the third dam DAM3. However, according to an embodiment, the dams DAM1, DAM2, and DAM3 may have substantially the same height as each other.

At least two of the dams DAM1, DAM2, and DAM3 may have different stack structures from each other. As an example, the first dam DAM1 may include the same material as that of the third insulating layer INS12. Each of the second dam DAM2 and the third dam DAM3 may include a first layer P1 and a second layer P2, which may be sequentially stacked in the third direction DR3. The first layer P1 may include the same material as that of the third insulating layer INS12, and the second layer P2 may include the same material as that of the pixel definition layer PDL. The first dam DAM1, the first layer P1 of the second dam DAM2, and the first layer P1 of the third dam DAM3 may be substantially simultaneously formed in a process of forming the third insulating layer INS12, and the second layer P2 of the second dam DAM2 and the second layer P2 of the third dam DAM3 may be substantially simultaneously formed in a process of forming the pixel definition layer PDL. However, the disclosure should not be limited thereto or thereby. According to an embodiment, the dams DAM1, DAM2, and DAM3 may include the same material and may have the same structure.

The first encapsulation layer EN1 of the encapsulation layer TFE may extend from the display area DA to the non-display area NDA and may be disposed on the dams DAM1, DAM2, and DAM3. The first encapsulation layer EN1 of the encapsulation layer TFE may be in contact with the dams DAM1, DAM2, and DAM3.

The second encapsulation layer EN2 of the encapsulation layer TFE may be disposed on the first encapsulation layer EN1. The area in which the second encapsulation layer EN2 including the organic layer may be formed may be defined by the dams DAM1, DAM2, and DAM3. In the manufacturing process of the display substrate DP, the second encapsulation layer EN2 with fluidity may flow toward the non-display area NDA and may be blocked by one of the dams DAM1, DAM2, and DAM3. FIG. 8 shows a structure in which the flow of the second encapsulation layer EN2 may be blocked in the space between the first dam DAM1 and the second dam DAM2.

The third encapsulation layer EN3 may be disposed on the second encapsulation layer EN2 to cover the second encapsulation layer EN2. The third encapsulation layer EN3 may extend more than the second encapsulation layer EN2 toward an outer end of the non-display area NDA. Referring to FIG. 8, the third encapsulation layer EN3 may be disposed on the second dam DAM2 that blocks the flowing of the second encapsulation layer EN2 and the third dam DAM3 that may be disposed outside the second dam DAM2. The third encapsulation layer EN3 may be in contact with the second dam DAM2 and the first encapsulation layer EN1 disposed on the third dam DAM3 and may encapsulate the second encapsulation layer EN2 together with the first encapsulation layer EN1. Accordingly, the moisture or oxygen may be prevented from entering the second encapsulation layer EN2 from the outside.

The sealing member SAL may be disposed in the non-display area NDA. The sealing member SAL may be disposed on the second insulating layer INS11, however, it should not be limited thereto or thereby. The position where the sealing member SAL may be disposed may be changed depending on the arrangement of the insulating layer of the display substrate DP. As an example, the sealing member SAL may be disposed on the first insulating layer INS10 or may be in contact with the lower substrate SUB1. Although not shown in figures, some of the conductive patterns of the circuit layer DP-CL may be disposed between the insulating layers in the non-display area NDA, and according to an embodiment, some of the conductive patterns may overlap the sealing member SAL in a plan view.

The dams DAM1, DAM2, and DAM3 may be spaced apart from the sealing member SAL in a plan view. The dams DAM1, DAM2, and DAM3 may prevent the encapsulation layer TFE from extending toward the outer end of the non-display area NDA in which the sealing member SAL may be disposed.

The filling member FL may be disposed between the display substrate DP and the light control substrate LCM. In the coupling of the light control substrate LCM to the display substrate DP, the filling member FL may be filled in between the display substrate DP and the light control substrate LCM in the display area DA. The filling member FL may be formed by curing a resin with fluidity, however, it should not be limited thereto or thereby. According to an embodiment, the filling member FL may be omitted, and a gap may exist between the display substrate DP and the light control substrate LCM.

The filling member FL may be disposed spaced apart from the sealing member SAL in a plan view. As an example, one side surface L-FL of the filling member FL may be spaced apart from the sealing member, however, it should not be limited thereto or thereby. According to an embodiment, the filling member FL may be in contact with the sealing member SAL in some areas.

Referring to FIG. 8, the light conversion layer LCL may further include a dummy pattern PU. The bank portion BK may be disposed in the display area DA, and a portion of the bank portion BK may be disposed in the non-display area NDA. For example, some of the openings BK-OP of the bank portion BK may overlap the non-display area NDA, and the dummy pattern PU may be disposed in the opening BK-OP of the bank portion BK, which overlaps the non-display area NDA. The dummy pattern PU may be spaced apart from the light emitting element disposed in the display area DA in a plan view. Since the dummy pattern PU may not overlap the light emitting element, the light may not exit through the dummy pattern PU.

The dummy pattern PU may include a base resin and quantum dots. The light conversion portions WCP1 and WCP2 (referring to FIG. 7) may be formed by an inkjet method. Before the light conversion portions WCP1 and WCP2 (refer to FIG. 7) may be formed in the display area DA, a composition may be preliminarily coated on the area that may not overlap the light emitting element to prevent the uneven dispersion of the quantum dots in the light conversion portions WCP1 and WCP2 (refer to FIG. 7), which may be formed at an early stage of the process. The dummy pattern PU may correspond to a portion that may be preliminarily formed before the light conversion portions WCP1 and WCP2 (refer to FIG. 7) overlapping the light emitting element may be formed. However, according to an embodiment, the dummy pattern PU may be omitted.

Referring to FIGS. 8 and 9A, the color filter layer CFL may extend from the display area DA to the non-display area NDA. A portion of the color filter layer CFL disposed in the non-display area NDA may include the first, second, and third color filters CF1, CF2, and CF3 disposed to overlap each other in the third direction DR3.

The first, second, and third color filters CF1, CF2, and CF3 may be color filters having different colors from each other. As an example, each of the first, second, and third color filters CF1, CF2, and CF3 may be one of the green color filter, the red color filter, and the blue color filter. The first, second, and third color filters CF1, CF2, and CF3 disposed to overlap each other along the thickness direction of the display module DM may prevent the light from entering or exiting through the non-display area NDA. The first, second, and third color filters CF1, CF2, and CF3 disposed to overlap each other in the third direction DR3 may prevent the external light incident into the non-display area NDA from being reflected.

The first, second, and third color filters CF1, CF2, and CF3 may include rear surfaces R-1, R-2, and R-3 facing the display substrate DP, respectively. The second color filter CF2 may be disposed on the rear surface R-3 of the third color filter CF-3, and the first color filter CF-1 may be disposed on the rear surface R-2 of the second color filter CF-2.

A stack order of the first, second, and third color filters CF1, CF2, and CF3 should not be limited to that shown in figures. For instance, the stack order of the first, second, and third color filters CF1, CF2, and CF3 may vary depending on the order in which the first, second, and third color filters CF1, CF2, and CF3 may be formed during the manufacturing process of the light control substrate LCM.

The color filter layer CFL may include the first surface S1 facing the display substrate DP. The first surface S1 of the color filter layer CFL may be the rear surface (or the lower surface) of the color filter layer CFL. The first surface S1 of the color filter layer CFL may correspond to the rear surfaces R-1, R-2, and R-3 of the first, second, and third color filters CF1, CF2, and CF3, which face the display substrate DP and which may be in contact with the low refractive index layer LR.

Each of the first, second, and third color filters CF1, CF2, and CF3 may extend from the display area DA to the non-display area NDA. Edges E-1, E-2, and E-3 of the first, second, and third color filters CF1, CF2, and CF3 may be disposed at different positions from each other. For example, the edges E-1, E-2, and E-3 of the first, second, and third color filters CF1, CF2, and CF3 may not be aligned with each other.

As shown in FIG. 9A, the second color filter CF2 may extend more than the first color filter CF1 toward an outer side of the upper substrate SUB2. Accordingly, the edge E-2 of the second color filter CF2 may protrude more than the edge E-1 of the first color filter CF1 along a direction from a center of the upper substrate SUB2 toward the outer side of the upper substrate SUB2. The third color filter CF3 may extend more than the second color filter CF2 toward the outer side of the upper substrate SUB2. For example, the edge E-3 of the third color filter CF3 may protrude more than the edge E-2 of the second color filter CF2 along the direction from the center of the upper substrate SUB2 toward the outer side of the upper substrate SUB2.

The edge E-1 of the first color filter CF-1 may be disposed on the rear surface R-2 of the second color filter CF2. The edge E-2 of the second color filter CF-2 may be disposed on the rear surface R-3 of the third color filter CF3.

The first surface S1 of the color filter layer CFL may have the step difference ST. The step difference ST may be defined by a difference in height between the rear surfaces R-1, R-2, and R-3 of the first, second, and third color filters CF1, CF2, and CF3, which form the first surface S1 of the color filter layer CFL.

The step difference ST may include at least one step difference portion. FIG. 9A shows the step difference ST including a first step difference portion ST1 and a second step difference portion ST2 as a representative example. The first step difference portion ST1 may be formed by the rear surface R-1 of the first color filter CF1 and the rear surface R-2 of the second color filter CF2, which have a height difference (a first difference). The first difference may correspond to a thickness of the first color filter CF1. The second step difference portion ST2 may be formed by the rear surface R-2 of the second color filter CF2 and the rear surface R-3 of the third color filter CF3, which have a height difference (a second difference). The second difference may correspond to a thickness of the second color filter CF2.

In the non-display area NDA, the thickness of the first color filter CF1 may be different from the thickness of the second color filter CF2, however, it should not be limited thereto or thereby. According to an embodiment, the thickness of the first color filter CF1 may be substantially the same as the thickness of the second color filter CF2 in the non-display area NDA. The thicknesses of the color filters CF1, CF2, and CF3 may be changed depending on a design of the display module DM.

The step difference ST of the color filter layer CFL may be disposed closer to the outer side of the upper substrate SUB2 than the sealing member SAL is. For example, the step difference ST of the color filter layer CFL may be closer to the outer end of the non-display area NDA than a side surface L-SAL of the sealing member SAL is, however, it should not be limited thereto or thereby.

Referring to FIG. 9A, a distance d-1 from the edge E-1 of the first color filter CF1 to the edge E-2 of the second color filter CF2 may correspond to a pitch of the first step difference portion ST1. A distance d-2 from the edge E-2 of the second color filter CF2 to the edge E-3 of the third color filter CF3 may correspond to a pitch of the second step difference portion ST2. The pitch of the first step difference portion ST1 and the pitch of the second step difference portion ST2 may vary depending on a design of the color filters CF1, CF2, and CF3.

The low refractive index layer LR may be disposed on the first surface S1 of the color filter layer CFL. The low refractive index layer LR may be in contact with the first surface S1 of the color filter layer CFL. The low refractive index layer LR may extend from the display area DA to the non-display area NDA, and the low refractive index layer LR may be disposed on the step difference ST of the first surface S1. The low refractive index layer LR may be in contact with the rear surfaces R-1, R-2, and R-3 and the edges E-1, E-2, and E-3 of the first, second, and third color filters CF1, CF2, and CF3, which form the step difference ST.

As the color filter layer CFL has the step difference ST, the low refractive index layer LR disposed on the step difference ST may have a thin thickness in the non-display area NDA. As an example, the low refractive index layer LR may have the thickness equal to or greater than about tin in the display area DA, and the low refractive index layer LR may have the thickness equal to or smaller than about 1 μm in the non-display area NDA. In detail, the thickness of the low refractive index layer LR may be equal to or greater than about 1 μm and equal to or smaller than about 1.5 μm in the display area DA, and the thickness of the low refractive index layer LR may be equal to or smaller than about 0.5 μm in the non-display area NDA. However, the thickness of the low refractive index layer LR should not be limited thereto or thereby.

The thickness of the low refractive index layer LR in the non-display area NDA may be controlled by the distance between the edges E-1, E-2, and E-3 of the color filters CF1, CF2, and CF3, which form the step difference ST, for example, the pitch of the step difference portions ST1 and ST2, or the thickness of the color filters CF1, CF2, and CF3.

The low refractive index layer LR may include portions having different thicknesses according to areas in which the low refractive index layer LR may be disposed. As an example, the thickness of the low refractive index layer LR may decrease as a distance from the step difference ST decreases. Since the low refractive index layer LR has a thin thickness on the step difference ST of the color filter layer CFL, a continuity of the low refractive index layer LR on the step difference ST may be blocked.

Referring to FIG. 9B, the low refractive index layer LR may include of the intermittent portions (hereinafter, referred to as first, second, and third portions LP-1, LP-2, and LP-3) on the step difference ST. The first portion LP-1 of the low refractive index layer LR may be disposed on the rear surface R-1 of the first color filter CF1. The first portion LP-1 of the low refractive index layer LR may have a thickness that decreases as a distance from the step difference ST decreases.

The second portion LP-2 of the low refractive index layer LR may be disposed on the first step difference portion ST1. The second portion LP-2 of the low refractive index layer LR may be in contact with the rear surface R-2 of the second color filter CF2 and the edge E-1 of the first color filter CF-1, which form the first step difference portion ST1. A continuity between the second portion LP-2 and the first portion LP-1 of the low refractive index layer LR may be blocked by a corner of the first color filter CF1.

The third portion LP-3 of the low refractive index layer LR may be disposed on the second step difference portion ST2. The third portion LP-3 of the low refractive index layer LR may be in contact with the rear surface R-3 of the third color filter CF3 and the edge E-2 of the second color filter CF2, which form the second step difference portion ST2. A continuity between the third portion LP-3 and the second portion LP-2 of the low refractive index layer LR may be blocked by a corner of the second color filter CF2.

As the low refractive index layer LR has the thin thickness or the continuity of the low refractive index layer LR in the non-display area NDA may be blocked, the path of gas or moisture flowing through the low refractive index layer LR from the outside may be blocked. Accordingly, components of the light control substrate LCM may be prevented from being deteriorated due to gas or moisture from the outside. Accordingly, a separation of the display substrate DP from the light control substrate LCM, which may be caused by gas or moisture from the outside, may be prevented. A spot due to the deterioration may be prevented from being viewed in the display area DA adjacent to the non-display area NDA, and a reliability of the display device DD (refer to FIG. 1) may be improved.

Referring to FIGS. 9A and 9B, the first capping layer CP1 may cover the low refractive index layer LR. The first capping layer CP1 may extend from the display area DA to the non-display area NDA and may cover an edge of the low refractive index layer LR. Accordingly, the first capping layer CP1 may encapsulate the low refractive index layer LR and may prevent moisture or gas from entering the low refractive index layer LR.

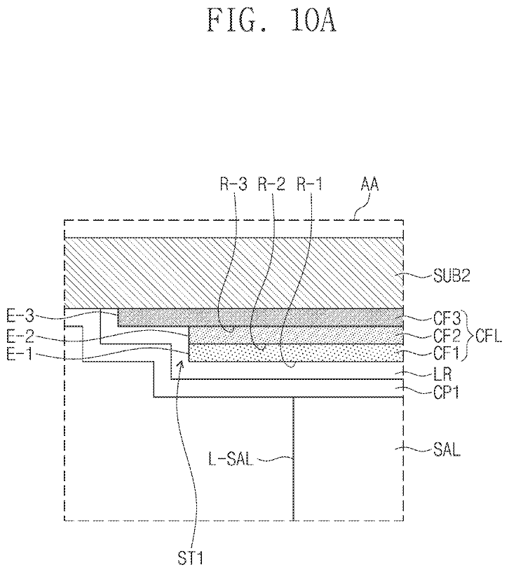

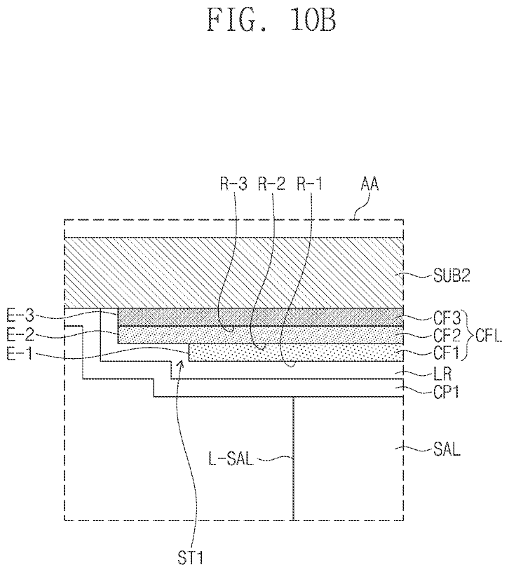

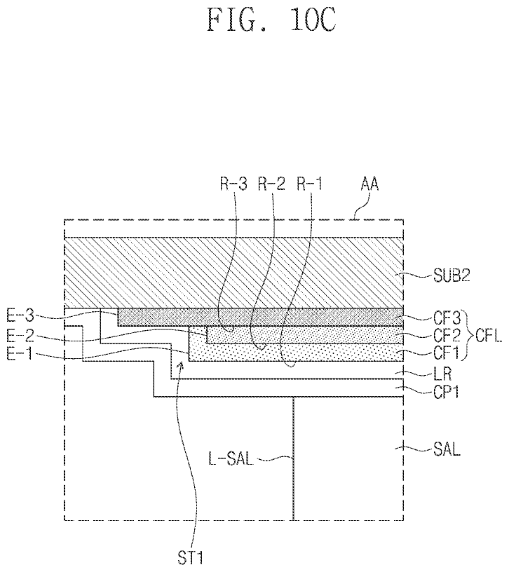

FIGS. 10A to 10C are enlarged schematic cross-sectional views of display modules in area AA of FIG. 8 according to embodiments of the disclosure. A shape or size of a step difference may be changed depending on an arrangement of first, second, and third color filters CF1, CF2, and CF3. FIGS. 10A to 10C show structures each in which the step difference of a color filter layer CFL may be provided as a step difference portion ST1.

Referring to FIG. 10A, edges E-1 and E-2 of the first color filter CF1 and the second color filter CF2 may be aligned with each other and may be disposed at a position different from a position at which an edge E-3 of the third color filter CF3 may be disposed. The edge E-3 of the third color filter CF3 may protrude more than each of the edges E-1 and E-2 of the first color filter CF1 and the second color filter CF2 in a direction toward an outer side of an upper substrate SUB2 from a center of the upper substrate SUB2. For example, the edge E-3 of the third color filter CF3 may be disposed closer to the outer side of the upper substrate SUB2 than each of the edges E-1 and E-2 of the first color filter CF1 and the second color filter CF2 is.

The edges E-1 and E-2 of the first color filter CF1 and the second color filter CF2 may be disposed on a rear surface R-3 of the third color filter CF3. A step difference portion ST1 may be formed by a rear surface R-1 of the first color filter CF1 and the rear surface R-3 of the third color filter CF3, which have a height difference, and the height difference may correspond to a sum of a thickness of the first color filter CF1 and a thickness of the second color filter CF2.

Referring to FIG. 10B, edges E-2 and E-3 of the second color filter CF2 and the third color filter CF3 may be aligned with each other and may be disposed at a position different from a position at which an edge E-1 of the first color filter CF1 may be disposed. The edges E-2 and E-3 of the second color filter CF2 and the third color filter CF3 may protrude more than the edge E-1 of the first color filter CF1 in a direction toward an outer side of an upper substrate SUB2 from a center of the upper substrate SUB2 and may be closer to the outer side of the upper substrate SUB2 than the edge E-1 of the first color filter CF1 is.

The edge E-1 of the first color filter CF1 may be disposed on a rear surface R-2 of the second color filter CF2. A step difference portion ST1 may be formed by a rear surface R-1 of the first color filter CF1 and the rear surface R-2 of the second color filter CF2, which have a height difference, and the height difference may correspond to a thickness of the first color filter CF1.

Referring to FIG. 10C, an edge E-3 of the third color filter CF3 may protrude more than an edge E-1 of the first color filter CF1 in a direction toward an outer side of an upper substrate SUB2 from a center of the upper substrate SUB2 and may be closer to the outer side of the upper substrate SUB2 than the edge E-1 of the first color filter CF1 is. An edge E-2 of the second color filter CF2 may be disposed inside the first color filter CF1. Accordingly, the edge E-2 of the second color filter CF2 may be covered by the first color filter CF1.

The edge E-1 of the first color filter CF1 may be disposed on a rear surface R-3 of the third color filter CF3. A step difference portion ST1 may be formed by a rear surface R-1 of the first color filter CF1 and the rear surface R-3 of the third color filter CF3, which have a height difference, and the height difference may correspond to the largest thickness of the first color filter CF1 covering the second color filter CF2.

FIGS. 10A to 10C show the structures each in which a low refractive index layer LR may be integrally formed on the step difference portion ST1 as a representative example, however, it should not be limited thereto or thereby. According to an embodiment, the low refractive index layer LR may include multiple portions whose continuity may be blocked on the step difference portion ST1.

According to the disclosure, the color filter layer may include a surface with the step difference, and the low refractive index layer may be disposed on the surface of the color filter layer, which has the step difference. The low refractive index layer may have the thin thickness on the step difference of the color filter layer, or the continuity of the low refractive index layer may be blocked on the step difference of the color filter layer. Therefore, the path of gas or moisture flowing through the low refractive index layer adjacent to the edge of the display device may be blocked, and the deterioration of the display device may be prevented.

According to the disclosure, since the display device includes the low refractive index layer that blocks the path of gas or moisture, the light emitting efficiency may be improved by the low refractive index layer, and the separation between the substrates of the display device or the occurrence of the spot in the area adjacent to the edge of the display device may be prevented. As a result, the reliability of the display device may be improved.

Although embodiments of the disclosure have been described, it is understood that the disclosure should not be limited to these embodiments but various changes and modifications can be made by one of ordinary skill in the art within the spirit and scope of the disclosure.

Therefore, the disclosed subject matter should not be limited to any single embodiment described herein.

What is claimed is:

1. A display device comprising:
a display substrate comprising:
a display area;
a non-display area adjacent to the display area; and
light emitting elements disposed in the display area; and
a light control substrate facing the display substrate and comprising:
a color filter layer;
a light conversion layer; and
a low refractive index layer disposed between the color filter layer and the light conversion layer, wherein
the color filter layer extends from the display area to the non-display area and comprises a first surface facing the display substrate, and
the first surface comprises a step difference overlapping the non-display area.

2. The display device of claim 1, wherein
the color filter layer comprises a first color filter, a second color filter, and a third color filter that each comprise a rear surface extending from the display area to the non-display area and facing the low refractive index layer, and
the first color filter, the second color filter, and the third color filter overlap each other in the non-display area.

3. The display device of claim 2, wherein an edge of the first color filter is disposed on the rear surface of the second color filter to form the step difference.

4. The display device of claim 2, wherein an edge of the first color filter is disposed on the rear surface of the third color filter to form the step difference.

5. The display device of claim 2, wherein
the step difference comprises a first step difference portion and a second step difference portion,
an edge of the first color filter is disposed on the rear surface of the second color filter to form the first step different portion, and
an edge of the second color filter is disposed on the rear surface of the third color filter to form the second step different portion.

6. The display device of claim 1, wherein the low refractive index layer covers the step difference.

7. The display device of claim 1, wherein the low refractive index layer comprises:
a first portion; and
a second portion spaced apart from the first portion in the non-display area.

8. The display device of claim 1, wherein the low refractive index layer has a thickness that decreases as a distance from the step difference decreases.

9. The display device of claim 2, wherein the first color filter, the second color filter, and the third color filter have different colors relative to each other.

10. The display device of claim 2, wherein
the light conversion layer comprises:
a bank portion including openings defined therethrough to correspond to the light emitting elements; and
a light conversion portion and a light transmission portion that are disposed in the openings, and the light conversion portion comprises a quantum dot converting a wavelength of a source light of the light emitting element.

11. The display device of claim 10, wherein the first color filter, the second color filter, and the third color filter overlap each other in an area in which the bank portion is disposed.

12. The display device of claim 10, wherein the low refractive index layer has a refractive index less than a refractive index of the light conversion portion.

13. The display device of claim 10, wherein
the light conversion portion comprises:
a first light conversion portion converting the source light to a first color light; and
a second light conversion portion converting the source light to a second color light,
the first color filter overlaps the first light conversion portion,
the second color filter overlaps the second light conversion portion, and
the third color filter overlaps the light transmission portion.

14. The display device of claim 1, wherein the light control substrate further comprises a capping layer that is in contact with the low refractive index layer and covers an edge of the low refractive layer.

15. The display device of claim 1, further comprising:
a sealing member disposed between the display substrate and the light control substrate to overlap the non-display area, wherein
the step difference is disposed closer to an outer side of the light control substrate than the sealing member is in a plan view.

16. A display device comprising:
a display substrate comprising:
a display area;
a non-display area adjacent to the display area; and
light emitting elements disposed in the display area;
an upper substrate comprising a rear surface facing the display substrate;
a color filter layer disposed on the rear surface of the upper substrate;
a light conversion layer disposed between the display substrate and the color filter layer; and
a low refractive index layer disposed between the color filter layer and the light conversion layer, wherein
the color filter layer comprises a first color filter, a second color filter, and a third color filter that extend from the display area to the non-display area and are sequentially disposed in a direction from the low refractive index layer to the upper substrate,
an edge of the third color filter protrudes more than an edge of the first color filter toward an outer side of the upper substrate, and
the edge of the first color filter is covered by the low refractive index layer.

17. The display device of claim 16, wherein an edge of the second color filter is aligned with the edge of the first color filter.

18. The display device of claim 16, wherein an edge of the second color filter is aligned with the edge of the third color filter.

19. The display device of claim 16, wherein an edge of the second color filter is covered by the first color filter.

20. The display device of claim 16, wherein
an edge of the second color filter protrudes more than the edge of the first color filter toward the outer side of the upper substrate, and
the edge of the third color filter protrudes more than the edge of the second color filter toward the outer side of the upper substrate.
